(19) United States
(12) Patent Application Publication
(10) Pub. No.: US 2024/0264237 A1
(43) Pub. Date: Aug. 8, 2024

(54) EVALUATION DEVICE, EVALUATION SYSTEM, EVALUATION METHOD AND ITS STORAGE MEDIUM

(71) Applicant: KABUSHIKI KAISHA TOYOTA CHUO KENKYUSHO, Nagakute-shi, Aichi-ken (JP)

(72) Inventors: Hirofumi HAZAMA, Nagakute-shi, Aichi-ken (JP); Hiroki KONDO, Nagakute-shi, Aichi-ken (JP)

(73) Assignee: KABUSHIKI KAISHA TOYOTA CHUO KENKYUSHO, Nagakute-shi, Aichi-ken (JP)

(21) Appl. No.: 18/567,052

(22) PCT Filed: May 23, 2022
(86) PCT No.: PCT/JP2022/021067

§ 371 Date: Dec. 5, 2023

(30) Foreign Application Priority Data
Jul. 15, 2021 (JP) 2021-117063

(51) Int. Cl. G01R 31/3842; G01R 31/392

(52) U.S. Cl. CPC G01R 31/3842; G01R 31/392

(57) ABSTRACT

An evaluation device includes: a first database that contains as data a measurement factor of a first type power storage device; a second database that contains as data a measurement factor of a second type power storage device which is different from the first type; and a conversion model that converts the data by machine learning. The evaluation device converts the data in the first database to the data in the second database using the conversion model, obtains a post-conversion database with data points greater in number than data points of the second database, and performs evaluation related to the second type power storage device using the post-conversion database.

### TECHNICAL FIELD

The present description discloses an evaluation device, an evaluation system, an evaluation method and its program.

### BACKGROUND ART

As the conventional method for evaluating a power storage device, for example, a deterioration diagnosis method for a lithium-ion secondary battery by machine learning using an AC impedance method and a pattern classification algorithm has been proposed (see, for example, PTL 1). By this evaluation method, deterioration of a lithium-ion battery or the like can be quickly determined. In addition, as the method for estimating capacity deterioration of a power storage device, a method of estimating capacity deterioration has been proposed (see, for example, PTL 2) in which capacity deterioration diagnosis is performed by multiple regression analysis using measurement results of an AC impedance. As the method for evaluating a power storage device, a method for estimating capacity deterioration has been proposed (see, for example, PTL 3). In the method, the type of a lithium-ion battery, a nickel-cadmium battery or a nickel-metal hydride battery is detected, and capacity deterioration is estimated in terms of the charge time of a corresponding charge control system, for example, in terms of a constant-current charge (CC) time for a lithium-ion battery. As the method for evaluating a power storage device, a method has been proposed (see, for example, PTL 4) in which analysis is made by an equivalent circuit based on measurement values of voltage and current, and a given battery is identified to be one of a lead battery, a nickel-metal hydride battery, a lithium-ion battery, and a nickel-cadmium battery based on the values. In this method, the technique of neural network, or support vector machine is recommended.

As the method for evaluating a power storage device, a method has been proposed (see, for example, PTL 5) in which a training data set (such as a voltage, a current, a temperature, an internal resistance) is collected using a battery cycling device, and battery cell operational characteristics are predicted by machine learning. As the method for evaluating a power storage device, a method has been proposed (see, for example, PTL 6) in which constant-current (CC) charge is performed, and upon reaching Vc, is switched to constant-voltage (CV) charge, then a capacity is estimated using a charge current value It when time t has elapsed since switching. As the method for evaluating a power storage device, a method has been proposed (see, for example, PTL 7) in which the magnetic field at the time of electric discharge is measured, and capacity deterioration is evaluated. As the method for evaluating a power storage device, a method has been proposed (see, for example, PTL 8) in which a volume change is sensed by a strain gauge, and deterioration due to expansion of the battery can be estimated even in a region where no capacity deterioration has occurred. As the method for evaluating a power storage device, a method has been proposed (see, for example, PTL 9) in which positive and negative pulse currents are applied, and resistance deterioration is estimated from a relationship between the voltage values for positive and negative. As the method for evaluating a power storage device, a method has been proposed (see, for example, PTL 10) in which an internal resistance and a remaining capacity (State Of Charge: SOC) are calculated from temperature, current, voltage, and deterioration evaluation is performed based on those.

### CITATION LIST

### Patent Literature

PTL 1: JP 2016-90346 A
PTL 2: JP 2014-44149 A
PTL 3: JP H11-329512 A
PTL 4: JP2014-178213 A
PTL 5: JP 2019-113524 A
PTL 6: JP 2001-257008 A
PTL 7: JP 2014-89819 A
PTL 8: JP 2020-24808 A
PTL 9: JP 2020-20715 A
PTL 10: JP 2010-261807 A

### SUMMARY OF INVENTION

### Technical Problem

However, in PTLs 1, 2 described above, battery deterioration diagnosis is performed by combination of an A.C. impedance method and machine learning; however, when the referred database does not have a sufficient data volume, prediction accuracy is not improved, and thus a sufficient reference database needs to be prepared. Also, in PTLs 3 to 8, when the referred database does not have a sufficient data volume, prediction accuracy is not improved, thus a sufficient reference database needs to be prepared. Particularly, when deterioration diagnosis is performed on a plurality of types of battery, a sufficient reference database for the battery types needs to be prepared to identify a battery type and perform deterioration diagnosis for the battery type.

The present disclosure has been made in consideration of such a problem, and it is a main object to provide novel evaluation device, evaluation system, evaluation method and its program that can evaluate a power storage device more efficiently with improved accuracy.

### Solution to Problem

In order to achieve the above-mentioned object, the inventors have intensively studied and found out that when a type of database with a smaller number of data points is diverted to a different type of database using machine learning, a power storage device can be evaluated with a higher efficiency due to reduced data measurements and improved accuracy, and consequently, the invention disclosed in the present description has been completed.

Specifically, the evaluation device disclosed in the present description is

an evaluation device that evaluates a power storage device including a plurality of types,

the evaluation device comprising a controller including a first database that contains as data a measurement factor of a first type power storage device; a second database that contains as data a measurement factor of a second type power storage device different from the first type power storage device; and a conversion model that converts data by machine learning using the measurement factors of the power storage devices, the controller being configured to convert the data in the first database to the data in the second database using the conversion model, obtain a post-conversion database with data points greater in number than data points of the second database, and perform evaluation related to the second type power storage device using the post-conversion database.

The evaluation system disclosed in the present description includes:

a measurement device that obtains a measurement result of a measurement factor of a power storage device; and

the above-described evaluation device.

The controller obtains the measurement result of the power storage device from the measurement device.

The evaluation method disclosed in the present description is

an evaluation method for performing evaluation of a power storage device including a plurality of types.

A first database that contains as data a measurement factor of a first type power storage device; a second database that contains as data a measurement factor of a second type power storage device different from the first type power storage device; and a conversion model that converts data by machine learning using the measurement factors of the power storage devices are provided, the evaluation method including: a conversion step for converting the data in the first database to the data in the second database using the conversion model, and obtaining a post-conversion database with data points greater in number than data points of the second database; and

an evaluation step for performing evaluation related to the second type power storage device using the post-conversion database.

The program disclosed in the present description causes one or a plurality of computers to execute the steps in the above-described evaluation method. This program may be recorded on a computer-readable recording medium (e.g., a hard disk, a ROM, a FD, a CD, a DVD), or may be distributed from a computer to another computer via a transmission medium (a communication network such as the Internet and a LAN), or may be delivered in any other form.

### Advantageous Effects of Invention

The evaluation device, the evaluation system, the evaluation method and its program of the present disclosure can evaluate a power storage device more efficiently with improved accuracy. The reason why the present disclosure provides such effects can be inferred as follows. For example, in order to estimate the performance of a power storage device with high accuracy, measurement factors such as measurement data of the power storage device are required to be enriched. In the present disclosure, a database already prepared is diverted to a database with an insufficient number of data points using machine learning, thereby expanding the database. Thus, without preparing an enriched database, it is possible to perform abnormal value detection for deterioration diagnosis of a power storage device, type determination, and additionally estimation of the capacity and the resistance of a power storage device with high accuracy. As a result, for example, deterioration diagnosis of a power storage device can be increased in accuracy. Therefore, in the present disclosure, a power storage device can be evaluated more efficiently with improved accuracy. Here, the “type” also includes a product type of the same power storage device type, in addition to the type of power storage device itself, such as a lead battery, a nickel-metal hydride battery, a lithium-ion battery, for example. In addition, the “product type” also includes different types (brand a and brand b of A company, or A company product and B company product) in the same power storage device type (e.g., a lithium-ion secondary battery).

### BRIEF DESCRIPTION OF DRAWINGS

FIG. 1 is an explanatory view showing an example of an evaluation system 10.

FIG. 2 is a flowchart showing an example of a conversion process routine.

FIG. 3 is a flowchart showing an example of an estimation model construction process routine.

FIG. 4 is a flowchart showing an example of a deterioration degree determination process routine.

FIG. 5 is an explanatory view of a display screen 40 showing a diagnosis result.

FIG. 6 is a scheme for illustrating a relationship between conversion process, outlier detection, and deterioration estimation.

FIG. 7 shows measurement results of a new battery and a deteriorated battery of lithium-ion secondary battery (LIB).

FIG. 8 is a relationship graph between deteriorated batteries and evaluation values of LOF.

FIG. 9 is a measurement result showing frequency dependence of the real parts of impedance of new batteries and deteriorated batteries.

FIG. 10 is a measurement result showing frequency dependence of the imaginary parts of impedance of new batteries and deteriorated batteries.

FIG. 11 is a relationship graph between experimental capacity value and predicted capacity value.

FIG. 12 is a relationship graph between experimental capacity value and predicted resistance value.

FIG. 13 is a relationship graph between frequency (Hz) and measurement time (s).

FIG. 14 is a relationship graph between number of measurement points and RMSE (mAh).

FIG. 15 is a relationship graph between direct measurement of impedance and indirect measurement by current step method.

FIG. 16 is a relationship graph between experimental capacity value and predicted capacity value which are predicted based on single type or mixed three types.

FIG. 17 is a relationship graph between predicted value using a prediction model and actual measured value.

FIG. 18 is an example of impedance of a new battery with SOC of 50% at temperature 20° C.

FIG. 19 is a relationship graph between predicted value of impedance predicted by a conversion model and experimental value.

FIG. 20 is a relationship graph between data No. with abnormal data added and LOF of second batteries.

FIG. 21 is a relationship graph between the capacities of three second batteries and the capacities of corresponding first batteries.

FIG. 22 is a relationship graph between actual measured and predicted capacity values obtained by a prediction model using a post-conversion database.

FIG. 23 is a resultant graph of the capacity of a deteriorated battery predicted using a post-conversion database.

FIG. 24 is a resultant graph obtained through sorting in ascending order of LOF.

FIG. 25 is a relationship graph between LOF and frequency.

### DESCRIPTION OF EMBODIMENTS

### Evaluation Device

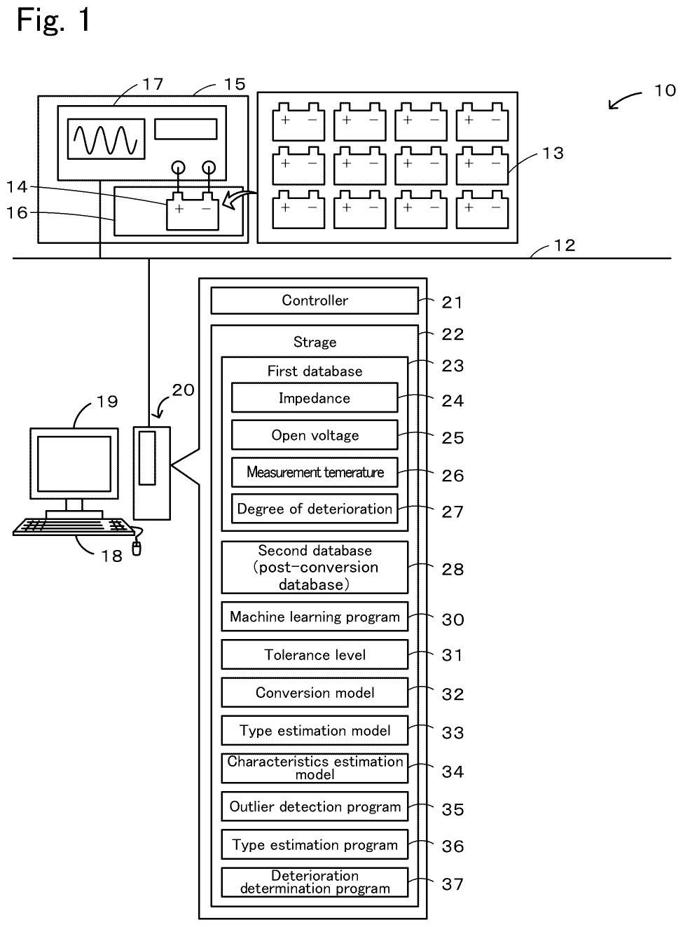

An embodiment of the evaluation device disclosed in the present description will be described below with reference to the drawings. FIG. 1 is an explanatory view showing an example of an evaluation system 10. The evaluation system 10 is installed, for example, in a collection facility that collects used power storage devices 13 to evaluate the characteristics, such as the degree of deterioration of each power storage device 13. The evaluation system 10 estimates the degree of deterioration of each collected power storage device 13, and determines whether the power storage device 13 is reusable or should be recycled. Reusable power storage devices 13 are readjusted and shipped, while power storage devices 13 to be recycled are recycled. The evaluation system 10 includes a measurement device 15 and an evaluation device 20. The evaluation system 10 exchanges information between the measurement device 15 and the evaluation device 20 via a network 12 including a LAN and the Internet.

As the power storage device 13, for example, a hybrid capacitor, a pseudo/electric double layer capacitor, a secondary battery of alkali metal such as lithium and sodium, an alkali metal ion battery, and an air battery may be mentioned. Between these, a lithium secondary battery, particularly, a lithium-ion secondary battery is preferable as the power storage device 13. Herein, a description is mainly given by assuming that the power storage device 13 is a lithium-ion secondary battery. The power storage device 13 may include, for example, a positive electrode, a negative electrode, and an ion-conducting medium interposed between the positive electrode and the negative electrode to conduct carrier ions. The positive electrode may contain sulfide containing a transition metal element, and/or an oxide containing lithium and a transition metal element as the positive-electrode active material. As the positive-electrode active material, it is possible to use, for example, a lithium-manganese composite oxide having a basic composition formula of Li₍₁₋ₓ₎MnO₂ (0<x<1, the same applies below) or Li₍₁₋ₓ₎Mn₂O₄, a lithium-cobalt composite oxide having a basic composition formula of Li₍₁₋ₓ₎CoO₂, a lithium-nickel composite oxide having a basic composition formula of Li₍₁₋ₓ₎NiO₂, and a lithium-nickel-cobalt-manganese composite oxide having a basic composition formula of Li₍₁₋ₓ₎NiₐCo_{b}Mn_{c}O₂ (a+b+c=1). Note that the “basic composition formula” means that other elements may be contained. The negative electrode may contain a composite oxide containing a carbon material and/or lithium as the negative-electrode active material. As the negative-electrode active material, for example, an inorganic compound such as lithium, lithium alloy, and a tin compound, a carbon material which can adsorb and desorb lithium ions, a composite oxide containing a plurality of elements, and a conductive polymer may be mentioned. As the carbon material, for example, cokes, glassy carbons, graphites, non-graphitizable carbons, pyrolytic carbons, carbon fiber may be mentioned. Between these, graphite, such as artificial graphite, natural graphite, is preferable. As the composite oxide, for example, a lithium-titanium composite oxide, and a lithium-vanadium composite oxide may be mentioned. The ion-conducting medium may be, for example, an electrolytic solution in which supporting salt is dissolved. As the supporting salt, for example, lithium salt such as LiPF₆ and LiBF₄ may be mentioned. As the solvent in the electrolytic solution, for example, carbonates, esters, ethers, nitriles, furans, sulfolane and dioxolanes may be mentioned, and these can be used independently or in a combined fashion. Specifically, as the carbonates, cyclic carbonates, such as ethylene carbonate, propylene carbonate, vinylene carbonate, butylene carbonate, chloroethylene carbonate, and chain carbonates, such as dimethyl carbonate, ethyl methyl carbonate, diethyl carbonate, ethyl-n-butyl carbonate methyl-t-butyl carbonate, di-i-propyl carbonate, and t-butyl-i-propyl carbonate may be mentioned. As the ion-conducting medium, a solid ion-conducting polymer, an inorganic solid electrolyte, a mixed material of an organic polymer electrolyte and an inorganic solid electrolyte, or inorganic solid powder bound by an organic binder may be utilized. In the solid electrolyte or the power storage device 13, a separator may be placed between the positive electrode and the negative electrode.

The measurement device 15 is a device that obtains measurement results of measurement factors of the power storage device 13. The measurement factors can be related to the characteristics of a power storage device, and may be, for example, the real part Z′ and the imaginary part Z″ of AC impedance, a measurement temperature T, an open voltage V, a charge current value It after lapse of time t, a magnetic field at the time of electric discharge, volume change of cell, voltage values when positive and negative pulse currents are applied, an internal resistance and a remaining capacity SOC may be mentioned. The measurement device 15 is a device that measures the AC impedance directly or indirectly as a measurement factor to determine the real part Z′ and the imaginary part Z″ of the impedance at measurement temperature T. In addition, the measurement device 15 can measure the open voltage V (V) of the power storage device 13. The measurement device 15 includes a constant temperature bath 16 that stores the power storage device 13 as a process target 14 adjusted at the measurement temperature T, and an AC impedance analyzer 17 electrically connected to the process target 14 to apply an AC current. The measurement device 15 may directly determine AC impedance, but may indirectly determine AC impedance, for example, by a current step method, a voltage step method, or a current pulse method. In the current step method, behavior of the voltage upon application of a predetermined current (e.g., 0.1 C) for a predetermined time (e.g., 0.01 s) is measured, and through the Laplace transform using the current and the voltage at this point, the real part Z′ and the imaginary part Z″ at a predetermined frequency (e.g., 100 Hz) can be determined. The measurement device 15 outputs a measurement result to the evaluation device 20 via the network 12.

The evaluation device 20 is a device that utilizes a characteristics estimation model 34 obtained from the results of measurement of a power storage device with a known degree of deterioration, and performs a deterioration degree estimation process of estimating the degree of deterioration of a process target 14 with an unknown degree of deterioration, from the results of measurement of the process target 14. The evaluation device 20 is a device that utilizes a type estimation model 33 obtained from the results of measurement of a power storage device with a known type, and performs a type estimation process of estimating the type of a process target 14 with an unknown type, from the results of measurement of the process target 14. In the databases to be used when the estimation process is performed, the evaluation device 20 performs a process of expanding a database with a smaller number of data points of measurement factor by machine learning using a conversion model for the data in a database with a greater number of data points. Here, the “type” includes not only a type which indicates a difference in the category of a power storage device itself, such as a difference between the positive-electrode active material and the negative-electrode active material, but also a product type including a difference in manufacturer and model number in the same category (e.g., “lithium-ion secondary battery”). The evaluation device 20 uses the measurement result of the process target 14, and when the measurement result is determined to be an outlier using a predetermined outlier detection technique, performs an outlier output process of outputting that effect. Note that the evaluation device 20 may use the same measurement factors or may use different measurement factors in the deterioration estimation process, the type estimation process and the outlier output process; however, it is efficient and preferable that the same measurement factors be used. The evaluation device 20 includes a controller 21, a storage 22, an input device 18, and a display device 19. The input device 18 includes a mouse and a keyboard for performing various types of input. The display device 19 displays a screen, and is, for example, a liquid crystal display.

The controller 21 is constituted as a microprocessor centered on a CPU, and controls the entire device. As functional blocks, the controller 21 includes: an obtainer that obtains a measurement result from the measurement device 15; a type estimator that estimates the type of the power storage device 13 from the obtained measurement result and the type estimation model 33; a detector that detects an outlier from the measurement result using a tolerance level 31; a deterioration estimator that derives a capacity and/or a resistance from the measurement result and the characteristics estimation model 34 to determine the degree of deterioration; and a determiner that determines whether the power storage device 13 as the process target 14 is reusable from the estimated degree of deterioration. These functional blocks are implemented by the controller 21 executing an outlier detection program 35, a type estimation program 36 and a deterioration determination program 37.

The storage 22 is constituted as a large-capacity storage device such as a HDD, for example, and includes a first database 23, a second database 28, a post-conversion database 29, a machine learning program 30, a tolerance level 31, a conversion model 32, a type estimation model 33, a characteristics estimation model 34, an outlier detection program 35, a type estimation program 36, and a deterioration determination program 37. The first database 23 includes, as data, measurement factors which are measurement results of a first type power storage device 13 with a known degree of deterioration, the first type being a specific product type. The first database 23 may be used to construct the type estimation model 33 and the characteristics estimation model 34. As measurement results, the first database 23 includes impedance 24, an open voltage 25, a measurement temperature 26, a degree of deterioration 27. The impedance 24 includes real part Z′ and imaginary part Z″. The degree of deterioration 27 indicates the degree of deterioration of the power storage device 13, and can be derived using the values of capacity and resistance, for example. For example, when the initial maximum discharge capacity is assumed to be 100%, the degree of deterioration 27 can be defined as the rate of a reduced maximum discharge capacity due to deterioration after continuous or intermittent use. Alternatively, for example, when the initial resistance is assumed to be 100%, the degree of deterioration 27 can be defined as the rate of increased resistance due to deterioration after continuous or intermittent use.

The second database 28 includes, as data, for example, measurement factors of measurement results in a second type power storage device 13 different from the first type in the first database 23. The second database 28 may include data points of, for example, a new product type which has a smaller number of data points than the first database 23. The second database 28 is updated to a post-conversion database by the later-described conversion process. The post-conversion database is associated with the power storage devices 13 of the same product type as the second database 28, and is produced by increasing the number of data points by machine learning using the first database 23. Here, the first database 23 may be assumed to have a greater number of data points than the second database 28. The first database 23 may be assumed to have had data of relevant type power storage devices 13 from an earlier time, and have accumulated and include a greater number of data points over a predetermined time period. For example, the first database 23 may include data points that are five times or greater, more preferably 10 times or greater, further preferably 50 times or greater, or 100 times or greater than those of the second database 28. The first database 23 used to expand data preferably has a greater number of data points, and preferably has 1000 points or greater, 3000 points or greater, 5000 points or greater, or 10000 points or greater data points, for example. In contrast, the second database 28 to be expanded with data preferably has a smaller number of data points from the point of view of the effort and time needed for measurement, and preferably has 1000 points or less, 500 points or less, 300 points or less, or 100 points or less data points, for example. The storage 22 is assumed to store the first database 23 and the second database 28, but may store other databases, such as a third database for third type power storage devices 13 and a fourth database for fourth type power storage devices 13. Note that the first database 23 and the second database 28 are collectively referred to as the “database” herein.

The machine learning program 30 is executed by the controller 21 to construct the conversion model 32, the type estimation model 33, and characteristics estimation model 34 from the first database 23 and the second database 28 by utilizing machine learning. For machine learning, for example, the statistical analysis software R, Python (registered trademark), SQL, Excel (registered trademark) can be used and one or more of linear regression, kernel ridge, support vector, XGBoost, neural network (nnet) and Random Forest (RF) can be used as the technique. As the technique for machine learning, Random Forest has higher accuracy of evaluation value, thus is preferable.

The tolerance level 31 is a threshold that is constructed based on a predetermined outlier detection technique using the measurement factors of power storage devices, for example. As the measurement factors, the real part Z′ of the impedance 24 of the first database 23 or the second database 28, the measurement temperature T, and the open voltage V of the power storage device 13 may be mentioned, and additionally, the imaginary part Z″ of the impedance 24 may be included. As the outlier detection technique, for example, LOF (Local outlier factor) Hotelling's Theory, K-Nearest Neighbor Method, and One-Class Support Vector Machine may be mentioned, and the LOF is preferable between these.

The conversion model 32 is a model that converts data by machine learning using the measurement factors of the power storage device 13, and performs a conversion process of expanding a database with a smaller number of data points with the data in another database. The conversion model 32 may be assumed to be constructed based on at least the real part Z′ of the impedance 24 of the first database 23 or the second database 28. The conversion model 32 is constructed based on at least the impedance 24, the measurement temperature T, and the open voltage V of the power storage device 13. The conversion model 32 is more preferably constructed based on additionally the imaginary part Z″ of the impedance. In particular, the conversion model 32 is most preferably constructed based on the real part Z′ and the imaginary part Z″ of the impedance 24, the measurement temperature T of the impedance 24, and the open voltage V of the power storage device 13.

The type estimation model 33 is a model for estimating the type of the power storage device 13. The type estimation model 33 may be assumed to be constructed based on at least the real part Z′ of the impedance 24 of the first database 23 of a known type power storage device 13, the measurement temperature T, and the open voltage V of the power storage device 13. The type estimation model 33 is more preferably constructed based on additionally the imaginary part Z″ of the impedance. In particular, the type estimation model 33 is most preferably constructed based on the real part Z′ and the imaginary part Z″ of the impedance 24, the measurement temperature T of the impedance 24, and the open voltage V of the power storage device 13.

The characteristics estimation model 34 is constructed for each type of the power storage device 13, and derives the characteristics (e.g., the capacity and the resistance) of the power storage device 13, then derives the degree of deterioration from the obtained characteristics. The characteristics estimation model 34 may be assumed to be constructed based on at least the real part Z′ of the impedance 24 of the first database 23, the measurement temperature T, and the open voltage V of the power storage device 13. The characteristics estimation model 34 is more preferably constructed based on additionally the imaginary part Z″ of the impedance of the power storage device 13 with a known degree of deterioration. In particular, the characteristics estimation model 34 is most preferably constructed based on the real part Z′ and the imaginary part Z″ of the impedance 24, the measurement temperature T of the impedance 24, and the open voltage V of the power storage device 13.

The conversion model 32, the type estimation model 33, and the characteristics estimation model 34 are preferably constructed based on the impedance in the range of 10⁻² Hz or higher and lower than 10⁴ Hz, and are more preferably constructed based on the impedance in the range of 10⁻¹ Hz or higher and 10³ Hz or lower. For example, the measurement temperature T may be higher than or equal to −30° C., may be higher than or equal to −20° C., or may be higher than or equal to −10° C. For example, the measurement temperature T may be lower than or equal to 60° C., may be lower than or equal to 50° C., or may be lower than or equal to 40° C. The measurement temperature T is preferably in the range of −20° C. or higher and 50° C. or lower. The measurement temperature T of the impedance should be set as appropriate based on the use environment of the power storage device 13.

The outlier detection program 35 is executed by the controller 21 to detect outliers using the tolerance level 31 from the measurement results of measurement factors, obtained by the measurement device 15. The outlier detection program 35 may derive an evaluation value by an outlier detection technique using, for example, at least the real part Z′ of the impedance, the measurement temperature T, and the open voltage V of the power storage device 13 as the process target, which are obtained from the measurement device 15. The outlier detection program 35 may also additionally obtain the imaginary part Z″ of the impedance to derive an evaluation value. The outlier detection program 35 may obtain the impedance of the process target 14 in the range of 10⁻² Hz or higher and lower than 10⁴ Hz, more preferably, in the range of 10⁻¹ Hz or higher and lower than 10³ Hz. For the outlier detection program 35, the measurement points for impedance to derive an evaluation value may be in the range of 10 or less, for example. The measurement points for impedance are more preferably 3 points or greater, and further preferably 4 points or greater. The measurement points are more preferably 8 points or less, and may be 6 points or less. The measurement points in the range of 3 points or greater and 10 or less can further increase the accuracy of detection of an outlier, thus are preferable. The outlier detection program 35 preferably obtains the impedance at measurement points including at least one point in the range of 10⁻² Hz or higher and 10⁰ Hz or lower as the lower end range, one point in the range higher than 10² Hz and lower than 10⁴ Hz as the upper end range, and one point in the range of 10⁰ Hz or higher and 10² Hz or lower as the intermediate range. Inclusion of at least one measurement point in each of the lower end range and the upper end range each can further increase the accuracy of detection of an outlier, thus is preferable. The lower end range is preferably the range of 10⁻¹ Hz or higher and lower than 100 Hz. In a low frequency band, the measurement time tends to be longer, thus in the outlier detection program 35, it is more preferable to use measurement points at a higher frequency even in the low frequency band.

The type estimation program 36 is executed by the controller 21 when the type of the process target 14 is estimated by the measurement results of the process target 14, and the type estimation model 33, then the characteristics estimation model 34 according to the type is set. The type estimation program 36 may estimate the type of the power storage device from the type estimation model 33 by using, as the explanatory variables, for example, at least the real part Z′ of the impedance of the power storage device 13 as the process target, the measurement temperature T, and the open voltage V which are obtained from the measurement device 15. The type estimation program 36 may also additionally obtain the imaginary part Z″ of the impedance, and may estimate the type of the process target 14 using the imaginary part Z″ as an explanatory variable. The type estimation program 36 may obtain the impedance of the process target 14 in the range of 10⁻² Hz or higher and lower than 10⁴ Hz, more preferably, in the range of 10⁻¹ Hz or higher and lower than 10³ Hz. For the type estimation program 36, the measurement points for impedance to estimate the type of the process target 14 may be in the range of 10 points or less, for example. The measurement points for impedance are more preferably 3 points or greater, and further preferably 4 points or greater. The measurement points are more preferably 8 points or less, and may be 6 points or less. The measurement points in the range of 3 points or greater and 10 points or less can further increase the accuracy of estimation of type, thus are preferable. The type estimation program 36 preferably obtains the impedance at measurement points including at least one point in the range of 10⁻² Hz or higher and 10⁰ Hz or lower as the lower end range, one point in the range higher than 10² Hz and lower than 10⁴ Hz as the upper end range, and one point in the range of 10⁰ Hz or higher and 10² Hz or lower as the intermediate range. Inclusion of at least one measurement point in each of the lower end range and the upper end range can further increase the accuracy of estimation of type, thus is preferable. The lower end range is preferably the range of 10⁻¹ Hz or higher and lower than 10⁰ Hz. In a low frequency band, the measurement time tends to be longer, thus in the type estimation program 36, it is more preferable to use measurement points at a higher frequency even in the low frequency band.

The deterioration determination program 37 is executed by the controller 21, and estimates the degree of deterioration of the process target 14 by the measurement results of the process target 14, and the characteristics estimation model 34, then determines whether the process target 14 is reusable. The deterioration determination program 37 may estimate the degree of deterioration of the power storage device from the characteristics estimation model 34 by using, as the explanatory variables, for example, at least the real part Z′ of the impedance of the power storage device 13 as the process target, the measurement temperature T, and the open voltage V which are obtained from the measurement device 15. The deterioration determination program 37 may also additionally obtain the imaginary part Z″ of the impedance, and may estimate the degree of deterioration of the process target 14 using the obtained imaginary part Z″ as an explanatory variable. The deterioration determination program 37 may obtain the impedance of the process target 14 in the range of 10⁻² Hz or higher and lower than 10⁴ Hz, more preferably, in the range of 10⁻¹ Hz or higher and lower than 10³ Hz. For the deterioration determination program 37, the measurement points for impedance to determine deterioration of the process target 14 may be in the range of 10 points or less, for example. The measurement points for impedance are more preferably 3 points or greater, and further preferably 4 points or greater. The measurement points are more preferably 8 points or less, and may be 6 points or less. The measurement points in the range of 3 points or greater and 10 points or less can further increase the accuracy of estimation of degree of deterioration, thus are preferable. The deterioration determination program 37 preferably obtains the impedance at measurement points including at least one point in the range of 10⁻² Hz or higher and 10⁰ Hz or lower as the lower end range, one point in the range higher than 10² Hz and lower than 10⁴ Hz as the upper end range, and one point in the range of 10⁰ Hz or higher and 10² Hz or lower as the intermediate range. Inclusion of at least one measurement point in each of the lower end range and the upper end range can further increase the accuracy of estimation of the degree of deterioration, thus is preferable. The lower end range is preferably the range of 10⁻¹ Hz or higher and lower than 10⁰ Hz. In a low frequency band, the measurement time tends to be longer, thus in the deterioration determination program 37, it is more preferable to use measurement points at a higher frequency even in the low frequency band.

### Evaluation Method

Next, the operation of thus configured evaluation device 20 in the present embodiment, particularly, the evaluation method performed by the evaluation device 20 will be described. The evaluation method is a method for performing evaluation of the power storage devices 13 including a plurality of types. The evaluation method may include: for example, a conversion step of converting the data in the first database 23 to the data in the second database 28 by machine learning using the conversion model 32, and obtaining a post-conversion database with data points greater in number than the data points of the second database 28; and an evaluation step of performing evaluation related to the second type power storage device using the post-conversion database. In addition, the evaluation method may further include, for example, a construction step of constructing the tolerance level 31, the type estimation model 33, and the characteristics estimation model 34 by machine learning. Note that in the evaluation method, the above-mentioned construction step may be omitted using the already constructed tolerance level 31, the type estimation model 33 and the characteristics estimation model 34.

### Conversion Step

Here, first, the conversion process of expanding a database with a smaller number of data points of measurement factor with another database will be described. In the conversion process, the data in the first database 23 is converted to the data in the second database 28 by machine learning using the conversion model 32, and a post-conversion database with data points greater in number than the data points of the second database 28 is obtained. In this process, the conversion model 32 may be constructed by associating the measurement factors of the first type with those of the second type one-to-one by machine learning. Note that herein, for the sake of convenience of explanation, the process of obtaining the second type post-conversion database using the first type first database 23 having a greater number of data points than the second type second database 28 will be mainly described. For machine learning to perform the conversion process, for example, the statistical analysis software R, Python (registered trademark), SQL, Excel (registered trademark) can be used and one or more of linear regression, kernel ridge, support vector, XGBoost, neural network (nnet) and Random Forest (RF) can be used as the technique. As the technique for machine learning, Random Forest is preferable because of its higher accuracy.

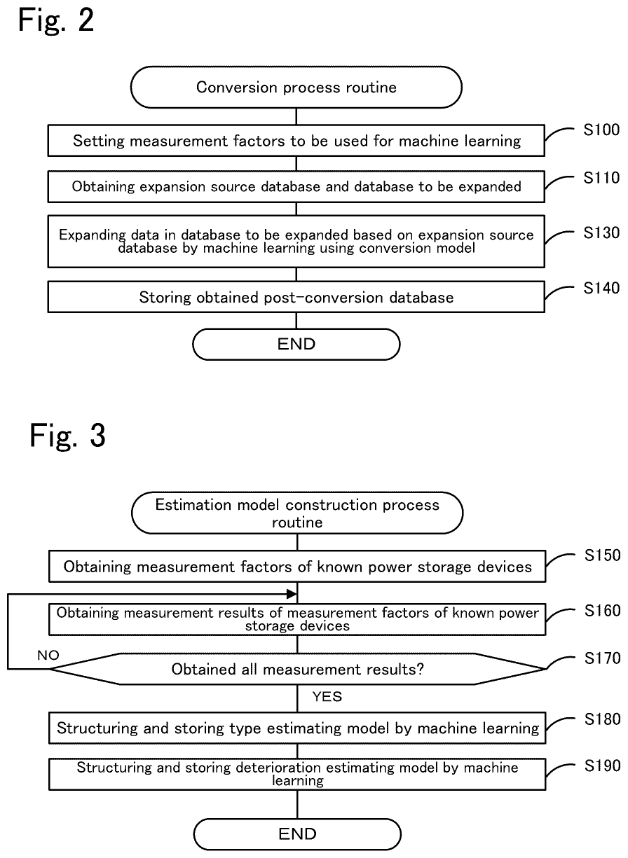

FIG. 2 is a flowchart showing an example of the conversion process routine performed by the controller 21. The routine is stored in the storage 22, and performed according to instructions of a user. When performing the routine, the controller 21 first sets the measurement factors to be used for machine learning (S100). As the measurement factors, the controller 21 can set the real part Z′, the imaginary part Z″ of impedance, the measurement temperature T and the open voltage V. Next, the controller 21 reads, from the storage 22, and obtains an expansion source database and a database to be expanded (S110). Here, for example, the second database 28 having a smaller number of data points is to be expanded, and the first database 23 having a greater number of data points is an expansion source. Subsequently, the controller 21 expands the data in the database (the second database 28) to be expanded based on the expansion source database (the first database 23) by machine learning using the conversion model 32 (S120). The controller 21 performs a process of converting the data in the first database 23 to the data in the second database 28 by machine learning using the conversion model 32 to increase the number of data points in the second database 28. At this point, the controller 21 performs a process of associating the measurement factors of the second type power storage device 13 with the measurement factors of the first type power storage device 13 one-to-one. For example, the controller 21 may perform machine learning using the impedance of the first type power storage device 13 as an object variable, and the impedance of the second type power storage device 13, the measurement temperature T, and the open voltage V as the explanatory variables. The controller 21 stores a database with an increased number of data points in the storage 22 as the post-conversion database (S140), and completes the routine. Subsequently, the controller 21 uses the obtained post-conversion database as the second database 28 for evaluation of the second type power storage device 13.

### Construction Step

Next, the process of constructing the tolerance level 31 will be described. In the construction process, a plurality of power storage devices 13 of known types and known degrees of deterioration are prepared by a user, and the evaluation system 10 uses the first database 23 and the second database 28 including the impedance 24, the open voltage 25, and the measurement temperature 26 as the measurement factors to derive an evaluation value using a predetermined outlier detection technique, and determine a threshold by which an outlier is properly detectable, and set the range of the threshold as the tolerance level 31. For example, when LOF is used as the outlier detection technique, a range of proper evaluation values and a distribution of evaluation values which are clearly outliers are obtained (see FIG. 8 mentioned below). From the distribution of evaluation values, a threshold can be set which allows an outlier to be determined without false detection.

Next, the process of constructing the type estimation model 33 and the characteristics estimation model 34 will be described. In the construction process, the type estimation model 33 and the characteristics estimation model 34 are constructed using the impedance 24, the open voltage 25, and the measurement temperature 26 which serve as the measurement factors and are included in the first database 23 and the second database 28 with data points increased in number by machine learning. FIG. 3 is a flowchart showing an example of an estimation model construction process routine performed by the controller 21. The routine is stored in the storage 22, and performed according to instructions of a user. When performing the routine, the controller 21 first obtains, from the database, the measurement factors of the power storage devices 13 with known type and degree of deterioration (S150), and obtains the measurement results of the power storage devices 13 corresponding to the obtained measurement factors (S160). Here, the impedance 24, the open voltage 25, and the measurement temperature 26 are set as the measurement factors. The controller 21 may directly obtain in real time the measurement results of the open voltage V and impedance, measured by the measurement device 15, while changing the process target 14, or may indirectly obtain the open voltage V already measured and the measurement results of impedance from the first database 23. The measurement results of impedance may include the imaginary part Z″ in addition to the real part Z′. After S160, the controller 21 determines whether the measurement results of all known power storage devices 13 have been obtained (S170), and when all the measurement results have not been obtained, the processes in and after S160 are repeatedly performed. In contrast, when all the measurement results have been obtained in S170, the controller 21 constructs the type estimation model 33 by machine learning, and stores it in the storage 22 (S180), and constructs the characteristics estimation model 34 by machine learning, and stores it in the storage 22 (S190), then completes the routine.

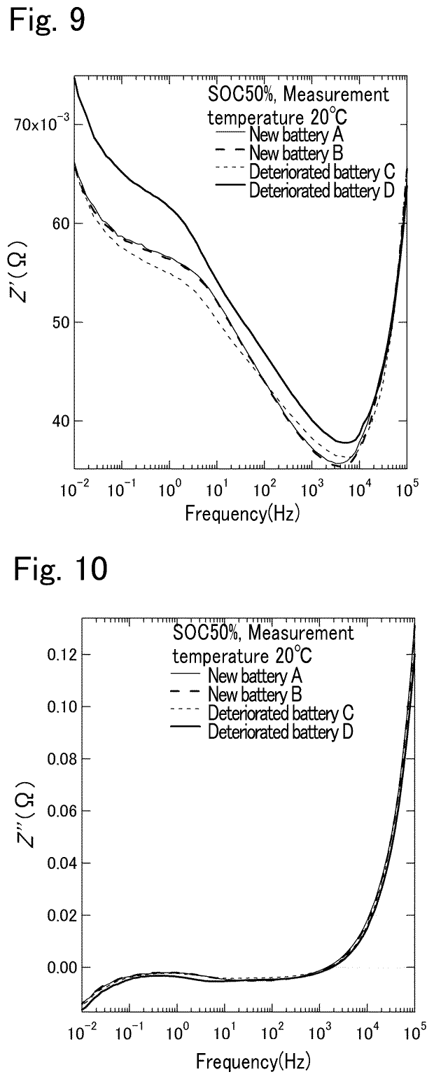

The impedance and the degree of deterioration of a deteriorated power storage device 13 do not have a linear relationship depending on the state of deterioration, and the impedance value of the deteriorated cell with respect to the initial cell may exhibit high impedance or may exhibit low impedance for each frequency band (see FIG. 9 mentioned below). Here, machine learning is utilized to construct the characteristics estimation model 34 that can estimate the degree of deterioration from the impedance Z′, Z″, the measurement temperature T, and the open voltage V. The power storage device 13 has a certain tendency in the change of the impedance and the change of the open voltage V depending on the type. Here, machine learning is utilized to construct the type estimation model 33 that can estimate the type of the power storage device 13 from the impedance Z′, Z″, the measurement temperature T, and the open voltage V. For example, for construction of the type estimation model 33 and the characteristics estimation model 34, the controller 21 can use the statistical analysis software R, Python (registered trademark), SQL, Excel (registered trademark) and, as the technique, can use one or more of linear regression, kernel ridge, support vector, XGBoost, neural network (nnet) and Random Forest (RF), preferably, Random Forest (RF).

### Evaluation Step

In the evaluation step, the measurement results of the measurement factors of the power storage device 13 as the process target 14 are used as the explanatory variables to estimate the type of the process target 14 from the type estimation model 33, and the measurement results are used as the explanatory variables to derive the capacity and/or the resistance of the power storage device 13 as the process target 14 from the characteristics estimation model 34 corresponding to the estimated type, thus the degree of deterioration is determined. In the evaluation step, an evaluation value is derived by an outlier detection technique using the measurement results of the measurement factors of the power storage device 13 as the process target 14, and the evaluation value that is out of the tolerance level 31 is output as an outlier. The measurement results with an evaluation value within the tolerance level 31 are used as the explanatory variables to derive the capacity and/or the resistance of the power storage device 13 from the characteristics estimation model 34, and the degree of deterioration is determined. In the evaluation step, a description is given where the measurement factors are the real part Z′ and/or the imaginary part Z″ of the impedance, the measurement temperature T, and the open voltage V. The type estimation model 33 and the characteristics estimation model 34 are assumed to be constructed for each of the types based on the database such as the first database 23 and the second database 28.

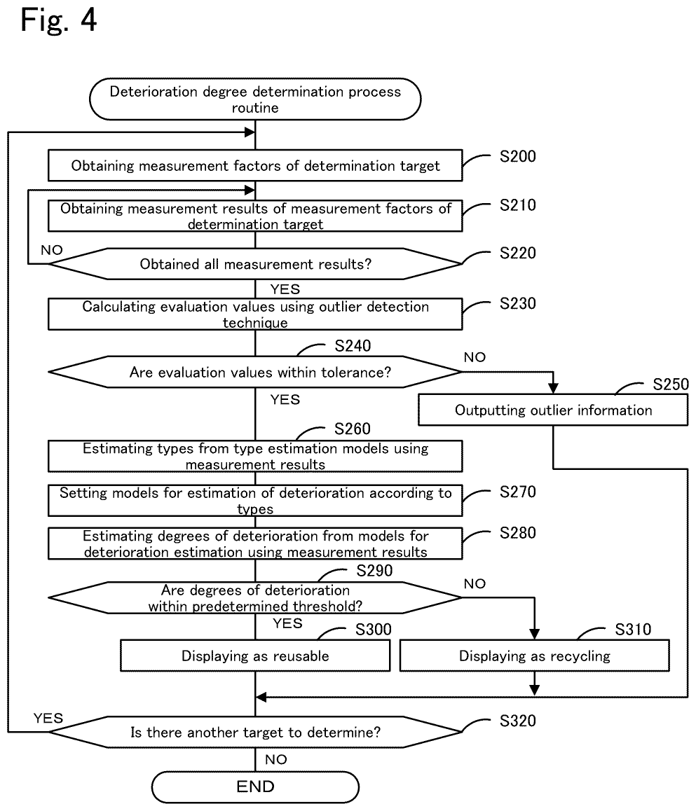

FIG. 4 is a flowchart showing an example of a deterioration degree determination process routine performed by the controller 21. The routine is stored in the storage 22, and performed according to instructions of a user. After constructing the tolerance level 31, the type estimation model 33 and the characteristics estimation model 34, a user connects the process target 14 (the power storage device 13) to the AC impedance analyzer 17, then causes the routine to be executed. When the routine is executed, the controller 21 obtains the measurement factors of the process target 14 (S200), and obtains the measurement results of the measurement factors of the process target 14 (S210). Here, as the measurement factors, the measurement points (frequency points) for impedance are also obtained in addition to the types (such as Z′, Z″, T, V) of the measurement factors. For example, in a specific frequency band, the measurement points are set in the range of 3 points or greater and 10 points or less, more preferably, the range of 4 points or greater and 8 points or less. As described above, the measurement points preferably include at least one point in the range of 10⁻² Hz or higher and 10⁰ Hz or lower as the lower end range, one point in the range higher than 10² Hz and lower than 10⁴ Hz as the upper end range, and one point in the range of 10⁰ Hz or higher and 10² Hz or lower as the intermediate range. When at least three measurement points are included in these ranges, the type and the degree of deterioration of the process target 14 can be estimated with higher accuracy. The measurement points may be included in the frequency range of 0.01 Hz or higher and 100000 Hz or lower, for example. Specifically, the measurement points may include 0.01 Hz, 0.1 Hz, 1 Hz, 10 Hz, 100 Hz, 1000 Hz, and 10000 Hz, 100000 Hz. The measurement points may include 0.05 Hz, 0.5 Hz, 5 Hz, 50 Hz, 500 Hz, 5000 Hz, 50000 Hz or 0.02 Hz, 0.2 Hz, 2 Hz, 20 Hz, 200 Hz, 2000 Hz, 20000 Hz. The measurement points preferably include, for example, 0.1 Hz, 1 Hz, 10 Hz, 100 Hz, 1000 Hz. As described above, for example, the measurement temperature T may be determined as appropriate in the range of −30° C. to 60° C. The measurement device 15 controls the constant temperature bath 16 at the set measurement temperature T, and measures the impedance by the AC impedance analyzer 17 at the set measurement points.

Next, the controller 21 determines whether all measurement results have been obtained (S220), and when all measurement results have not been obtained, performs the processes in and after S210. In S210, the controller 21 sets the next measurement point which has not been obtained. In contrast, when all measurement results are determined to be obtained in S220, the controller 21 uses the real part Z′ and/or the imaginary part Z″ of the impedance, the open voltage V, and additionally the measurement temperature T to calculate an evaluation value using an outlier detection technique (S230). The controller 21 calculates an evaluation value using LOF, for example. Subsequently, the controller 21 determines whether the evaluation value is within the tolerance level 31 (S240), and when the evaluation value is not within the tolerance level 31, in other words, when the evaluation value is out of the tolerance level 31, the controller 21 outputs outlier information (S250). The outlier information may include contents indicating that a measurement result of the process target 14 is an abnormal value. The output of the outlier information may be, for example, display output to the display device 19, may be audio output from a speaker which is not illustrated, may be print output from a printing device which is not illustrated, or may be storage output to the storage 22. After checking the outlier information, a user confirms the connection to the process target 14, and performs an operation such as re-measurement with the measurement device 15.

On the other hand, when the evaluation value is within the tolerance level 31 in S240, the controller 21 uses the measurement results to perform a process of estimating the type of the process target 14 from the type estimation model 33 (S260). The controller 21 uses the type estimation model 33 to derive the type most fitted to the measurement values of the explanatory variables for all measurement points. The type estimation model 33 is constructed by machine learning, and can estimate the type of the process target 14 with extremely high probability. Subsequently, the controller 21 sets the characteristics estimation model 34 according to the estimated type (S270), and uses the measurement results to estimate the degree of deterioration of the process target 14 from the characteristics estimation model 34 (S280). The controller 21 uses the characteristics estimation model 34 to derive the degree of deterioration most fitted to the measurement values of the explanatory variables for all measurement points. The characteristics estimation model 34 is constructed by machine learning, and can estimate the degree of deterioration of the process target 14 with extremely high probability. Subsequently, the controller 21 determines whether the estimated degree of deterioration is within a predetermined threshold (S290). The threshold is assumed to be empirically set based on the lower limit value which allows the power storage device 13 as the process target 14 to be reusable by re-adjustment, for example.

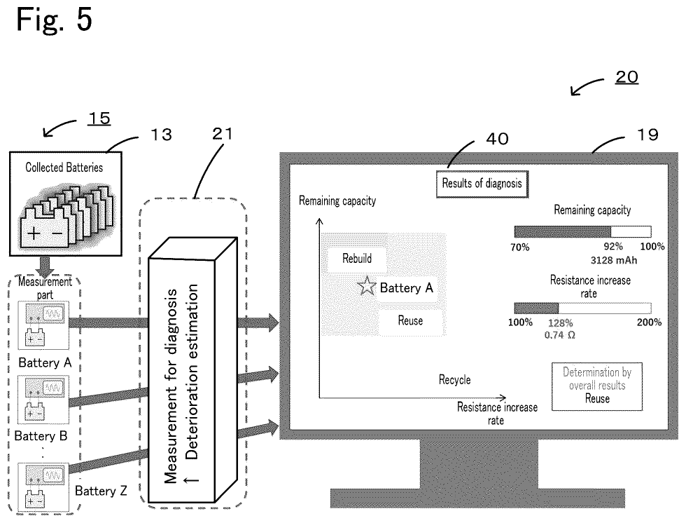

When the degree of deterioration of the process target 14 is within a predetermined threshold, the controller 21 outputs a display indicating that the power storage device 13 is reusable (S300). On the other hand, when the degree of deterioration of the process target 14 exceeds a predetermined threshold, the controller 21 outputs a display indicating that the process target 14 should be recycled (S310). FIG. 5 is an explanatory view of a display screen 40 showing a diagnosis result. As shown in FIG. 5, in addition to determination of recycling, reuse, determination of rebuilding to disassemble the process target 14 to utilize it as resources may be made, or information such as a remaining capacity and a resistance increase rate may be supplemented as a diagnosis result.

After S300, or after S310, or after S250, the controller 21 stores the determination results in S300, S310, S250, and determines whether there is a power storage device 13 as the next process target 14 (S320). When there is a next process target 14, the controller 21 repeatedly performs the processes in and after S200, whereas when there is no next process target 14 in S320, the controller 21 completes the routine. In this manner, in the evaluation device 20, the real part Z′ and/or the imaginary part Z″ of the AC impedance of the power storage device 13, the open voltage V, and additionally the measurement temperature T are used to detect outliers and exclude them, and determines whether the power storage device 13 is reusable by estimating the degree of deterioration of the process target 14 from the type estimation model 33 and the characteristics estimation model 34.

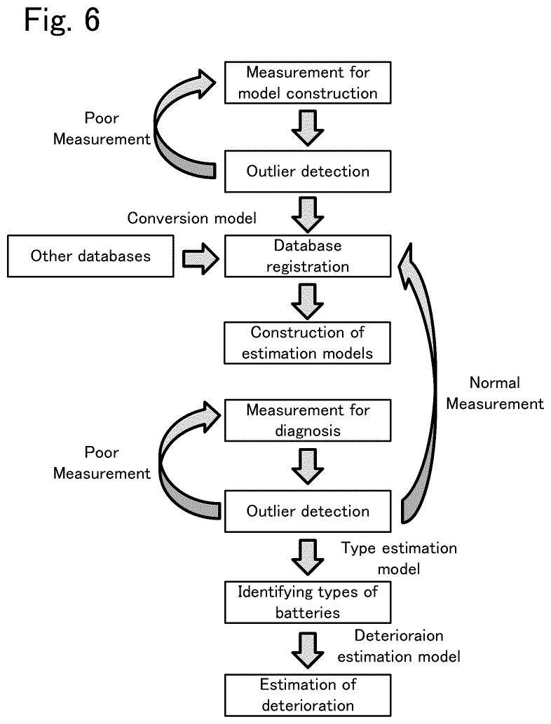

FIG. 6 is a scheme for illustrating a relationship between process of expanding a database, outlier detection, and deterioration estimation. In the evaluation device 20, first, measurement for model construction is made to prepare a database. In this case, outlier detection may be performed on the measurement data. A database with a smaller number of data points of measurement factor, such as a database for a new product type is expanded with the data in a database with a sufficient number of data points using the conversion model. A type estimation model and a characteristics estimation model are constructed using a database with the number of data points exceeding a predetermined threshold. Measurement for diagnosis is then performed on an unknown power storage device which is a process target. First, it is determined whether measurement is properly made, and when an outlier is detected, re-measurement is made because the outlier is regarded as poor measurement. The outlier detection has another role. When detection is made as data different from the database used for diagnosis model construction, detailed measurement is made on the power storage device, and results are incorporated into a database for diagnosis so that the type estimation model and the characteristics estimation model can be updated. When a detected value is considered to be a normal value by the outlier detection, the type of the power storage device is estimated using measurement values. When collected power storage devices include a plurality of types, it is more preferable that the type estimation be performed. When the types of the power storage devices can be identified, deterioration determination can be performed with higher accuracy by performing an estimation of deterioration using a characteristics estimation model according to the type of each of the power storage devices.

With the evaluation device 20 and the evaluation system 10 in the present embodiment described above, a power storage device can be evaluated more efficiently with further improved accuracy. The reason why the present disclosure provides the effects is inferred as follows. For example, in order to estimate the performance of a power storage device with high accuracy, measurement factors such as measurement data of power storage devices are required to be enriched. For example, as the major deterioration of a lithium-ion secondary battery which is a power storage device, three deterioration modes are known: “positive electrode deterioration”, “negative electrode deterioration” and “positive and negative electrode slippage”, which are common among the batteries of any product type. Thus, the sensitivity of response to deterioration varies with the product type of battery (impedance increases for deterioration), but almost no change occurs in tendency of the response. Thus, the axis of a database, for example, two axes of impedance for high-rate charge/discharge cycle deterioration and high-temperature storage deterioration are adjusted so that conversion between data with different battery types is made possible, thus it is inferred that diversion of the database is also made possible. In the present disclosure, a database already prepared is diverted to a database with an insufficient number of data points using machine learning, thereby expanding the database. Thus, without preparing an enriched database, it is possible to perform abnormal value detection for deterioration diagnosis of a power storage device, type determination, and additionally estimation of the capacity and the resistance of a power storage device with high accuracy. As a result, for example, deterioration diagnosis of a power storage device can be increased in accuracy. Therefore, in the present disclosure, a power storage device can be evaluated more efficiently with improved accuracy.

The power storage devices 13 for which deterioration determination is made may be different in details, for example, may be different in manufacturers even with the same type. In such a case, as compared to when an estimation model is constructed from all power storage devices 13 for performing deterioration determination, when an estimation model is constructed for each type, deterioration determination can be made with higher accuracy. By introducing an algorithm to identify the type of a power storage device, it is possible to estimate the type of a power storage device with high accuracy, and further increase the accuracy of deterioration determination. In addition, when the degree of deterioration of a power storage device is estimated using an outlier such as a result of poor measurement, an erroneous determination may be made. In contrast, in the present disclosure, evaluation values obtained by a predetermined outlier detection technique are used to inform of data of such an outlier in advance, thus an erroneous determination can be reduced. The details of a cell are examined, which is detected as an outlier due to a new phenomenon not found in the database used to construct an estimation model for deterioration estimation, and the details are incorporated into the database for estimation model construction, thereby making it possible to make prediction coping with the new phenomenon so that the prediction accuracy can be improved.

Note that the present disclosure is not limited to the above-described embodiment at all, and it is needless to say that an embodiment can be implemented in various manners as long as the embodiment belongs to the technical scope of the present disclosure.

For example, in the above-described embodiment, the evaluation system 10 includes the measurement device 15 and the evaluation device 20, but is not limited thereto, and the measurement results of measurement factors such as an AC impedance and an open voltage are to be obtained from the outside, and the measurement device 15 may be omitted. Even with the evaluation device 20, a power storage device can be evaluated more efficiently with further improved accuracy.

In the above-described embodiment, a description has been given with the AC impedance, the measurement temperature, and the open voltage serving as the measurement factors, but the measurement factors are not particularly limited to these as long as the power storage device 13 is evaluable with the factors. For example, evaluation of the power storage device 13 may be performed by the process shown in PTLs 6 to 10. As the measurement factor, for example, one or more of the following may be mentioned: a charge current value It when time t has elapsed since switching from constant-current (CC) charge to constant-voltage (CV) charge upon reaching Vc, a magnetic field at the time of electric discharge, a volume change of cell measured by a strain gauge, a relationship between positive and negative voltage values when positive and negative pulse currents are applied, an internal resistance and a remaining capacity SOC. In this case, a target for machine learning should be set to the measurement factor, and the conversion model 32, the type estimation model 33, and the characteristics estimation model 34 should be constructed.

In the above-described embodiment, the present disclosure has been described as the evaluation system 10, the evaluation device 20, the evaluation method, but may be described as a program for performing the evaluation method, for example. This program may be recorded on a computer-readable recording medium (e.g., a hard disk, a ROM, a FD, a CD, a DVD), or may be distributed from a computer to another computer via a transmission medium (a communication network such as the Internet and a LAN), or may be delivered in any other form. When the program is executed by one computer or the steps are shared and executed by a plurality of computers, each step in the above-described evaluation method is executed, thus the operational effects similar to those of the evaluation method are obtained.

### EXAMPLES

Hereinafter, a specifically studied example of the evaluation method and the evaluation device of the present disclosure will be described as an experimental example. Note that Experimental Examples 1 to 19 correspond to reference examples.

Lithium-ion battery NCR18650 manufactured by Panasonic was used to study the deterioration diagnosis as evaluation of used batteries, and results of impedance, open voltage, and measurement temperature were used for the diagnosis. For measurement of impedance, an open voltage, and a measurement temperature, CELLTEST-8T (7ch: 1A specifications, 1ch: 25A specifications) manufactured by Solar Tron Company was used, the current at the time of measurement was set to 5 mA, and the temperature of a constant temperature bath in which a measurement cell is placed was used as the measurement temperature T. Seven new batteries, and 35 deteriorated batteries were measured. As the deteriorated batteries, batteries with different deterioration modes were prepared, such as the ones which had been charged with 2 C between 2.5 V and 4.2 V at 20° C., and discharged with 0.1 C repeatedly, the ones which had been charged with 0.5 C at 60° C., and discharged with 0.1 C repeatedly, and the ones continued to be stored at 60° C. As lithium-ion secondary batteries of different types, 18650-M26 manufactured by LG, b18650-01 sold by PLATA were used, and batteries which had undergone charge and discharge cycles of 12, 24, 30, 36, 42, 48, 54 times with 2 C at 20° C. were prepared as deterioration modes. First, outliers included in the measurement data were studied, and determination of the degree of deterioration was made, then estimation of the type was studied. The impedance and the open voltage vary with the remaining capacity SOC of a battery and the measurement temperature, so measurement was made with SOC in the range of 0 to 100% with increments of 10%, and a measurement temperature in the range of −20 to 50° C. with increments of 10° C. As the index of the degree of deterioration, the battery capacity was used, and 5V/10A-80CH manufactured by Asuka Electronics Co., Ltd was used for each battery to set the battery capacity to the discharged capacity achieved by CV discharge with 0.1 C. The measurement conditions were such that the capacities of 42 batteries, and 88 conditions (11 SOC conditions×8 measurement temperature conditions) for each battery. Tables 1 to 4 collectively show the measurement conditions for each experimental example.

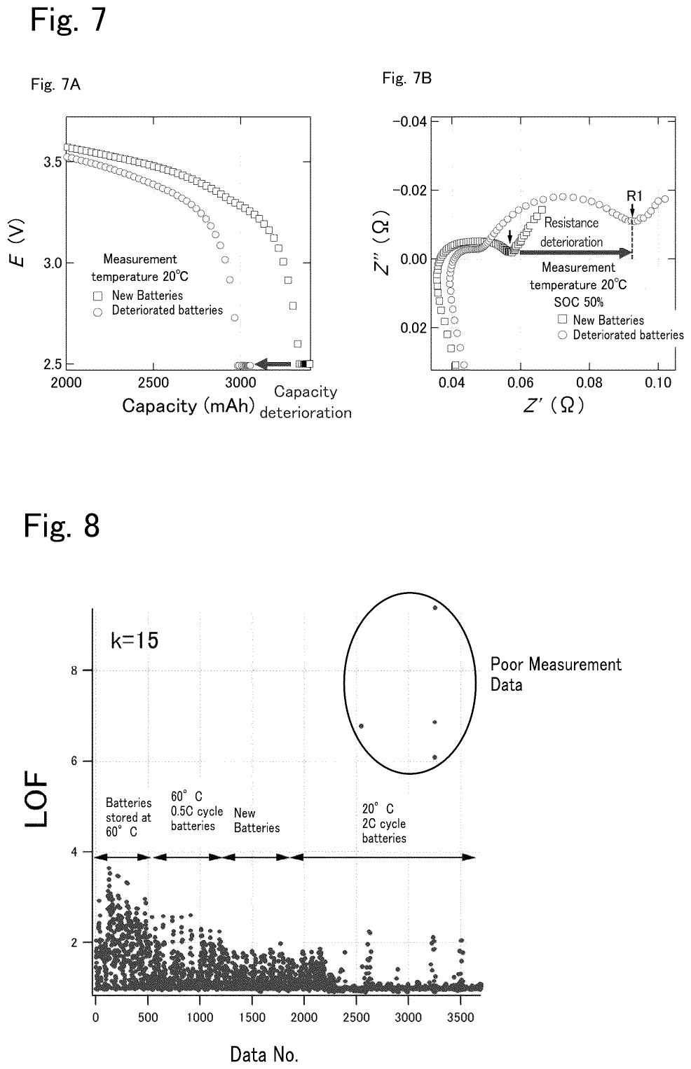

FIG. 7 shows measurement results of lithium-ion secondary batteries (LIB) manufactured by Panasonic, FIG. 7A shows the capacities of new batteries and deteriorated batteries, and FIG. 7B shows a difference in resistance between new batteries and deteriorated batteries. As shown in FIG. 7, it is seen that in the deteriorated batteries, the capacity decreases and the resistance increases as compared to the new batteries. Here, 5V/10A-80CH manufactured by Asuka Electronics Co., Ltd was used for each battery to measure the discharged capacity of CCCV discharge with 0.1 C at 20° C., and the battery capacity was determined to be the discharged capacity. The AC impedance was measured in detail with SOC of 50% at 20° C., and after charge transfer resistances of the positive and negative electrodes appeared as two arcs in the cole-cole plot shown in FIG. 7B, the real part Z′ when the imaginary part Z″ of the AC impedance attains a local minimum is defined as the characteristic resistance R1 of the battery, and used as an index for capacity as well as deterioration. The resistance R1 consists of resistance components having relatively quick response, and serves as an index for the resistance obtained by adding DC resistance and the charge transfer resistances of the positive and negative electrodes together.

First, the outliers in measurement data were studied. For machine learning to detect an outlier, the statistical analysis software R was used, and LOF (Local outlier factor) was used as the technique. FIG. 8 is an example of a relationship graph between deteriorated batteries (LIBs manufactured by Panasonic) and evaluation values of LOF. Here, the real part Z′ and the imaginary part Z″ of the AC impedance (0.1, 1, 10, 100, 1000 Hz), the open voltage (V), and the measurement temperature (C) were used as the parameters to calculate LOF, thus evaluation was made in a 12-dimensional space. A high score of LOF indicates a low density of data with respect to space, which can be regarded as an outlier. In FIG. 8, hyper parameter k is calculated with k=15, and the horizontal axis indicates the management number of battery data. For example, when the data at 4 data points with a LOF score of 6 or greater in FIG. 8 is checked, each measurement value of impedance indicates an abnormal value, and is an order of magnitude smaller than the normal data with the same measurement temperature and a close open voltage. In this manner, it has been found that poor measurement and abnormal measurement results can be extracted by calculating the measurement results for diagnoses together with the database used for diagnosis model construction, and using a tolerance level (e.g., the score of LOF is 4 or less).

Next, deterioration diagnosis of a lithium-ion battery was studied. FIG. 9 is a measurement result showing the frequency dependence of the real part Z′ of impedance of new batteries and deteriorated batteries with SOC of 50% at the measurement temperature 20° C. FIG. 10 is a measurement result showing the frequency dependence of the imaginary part Z″ of impedance of new batteries and deteriorated batteries with SOC of 50% at the measurement temperature 20° C. As shown in FIGS. 9 and 10, in the new batteries, the impedance exhibits substantially the same shape, value. In contrast, the deteriorated batteries exhibit the shape, value of impedance different from those of the new batteries. In the deteriorated batteries, for example, in the frequency band of 10¹ Hz or lower, Z′ of the deteriorated batteries is present above and below that of the new batteries depending on the difference in deterioration mode, in the frequency band of 10² Hz to 10⁴ Hz, Z′ of the deteriorated batteries is present above that of the new batteries, and at 10⁵ Hz, both batteries exhibit the same Z′, and a uniform tendency was not obtained. Thus, it was found that the amount of change in the impedance with respect to the degree of deterioration of the capacity cannot be explained by a simple model. The battery capacity was predicted from machine learning using the data set obtained.

For machine learning, the statistical analysis software R was used, caret was used as the package, and Random Forest (RF), neural network (nnet) were studied as the technique. The prediction accuracy was evaluated by Root Mean Square Error RMSE between experimental values and predicted values. A lower value of the RMSE indicates higher prediction accuracy. This time, in order to evaluate the versatility of an estimation model, 10-fold cross validation was performed to construct 10-time estimation model 10, and comparison and evaluation were made with the average RMSE for 10 times. Table 1 shows the result of prediction of battery capacity by each model. In Table 1, as the real part Z′ of impedance, the value of each frequency of 0.01, 0.1, 1, 10, 100, 1000, 10000, 100000 Hz was used. In addition, Table 1 summarizes the results of study of the open voltage V, and the measurement temperature T. As shown in Table 1, it has been found that when the open voltage V is included in the explanatory variables, the prediction accuracy is improved regardless of the technique for machine learning. In addition, it has been found that when the measurement temperature T is included in addition to the open voltage V, the prediction accuracy is further improved. It has been found that RF is higher in prediction accuracy than nnet as the technique for machine learning.

Table 2 summarizes the used frequency band dependence of the result of prediction of battery capacity by RF. As shown in Table 2, it was inferred that data for all frequencies does not need to be used, and there is an optimal frequency band to improve the prediction accuracy. For example, in the frequency band near 10000 Hz, the amount of change in impedance due to a capacity change becomes nearly equal to noise or an individual difference of a battery, thus it is necessary to limit the frequency band to improve the prediction accuracy. The upper limit range of measurement frequency band for impedance to determine the battery capacity is preferably, higher than 100 Hz and lower than 10000 Hz, and more preferably, higher than 100 Hz and lower than or equal to 1000 Hz. Regarding the lower limit range, even if it is changed from 0.01 Hz to 0.1 Hz, the prediction accuracy remains to be almost the same, and in the frequency band lower than 0.1 Hz, the measurement time rapidly increases as the frequency reduces, thus the lower limit range is preferably 0.1 Hz or higher. Table 3 shows RMSE which predicts a battery capacity by RF with changed combinations of explanatory variables by adding the imaginary part Z″ of the impedance. As shown in Table 3, it has been found that preferably, V is considered and T is further considered, more preferably, Z″ is further considered, and the prediction accuracy is improved when all of Z′, Z″, V, T are considered. When the imaginary part Z″, V, T are used as the explanatory variables (Experimental Example 14), an equivalent result to the case where the real part Z′, V, T are used as the explanatory variables (Experimental Example 11) is obtained, thus it is inferred that even when the imaginary part Z″ and the open voltage V are used as the explanatory variables, the degree of deterioration can be estimated with higher accuracy, as compared to when only the real part Z′ or only the imaginary part Z″ is used as an explanatory variable.

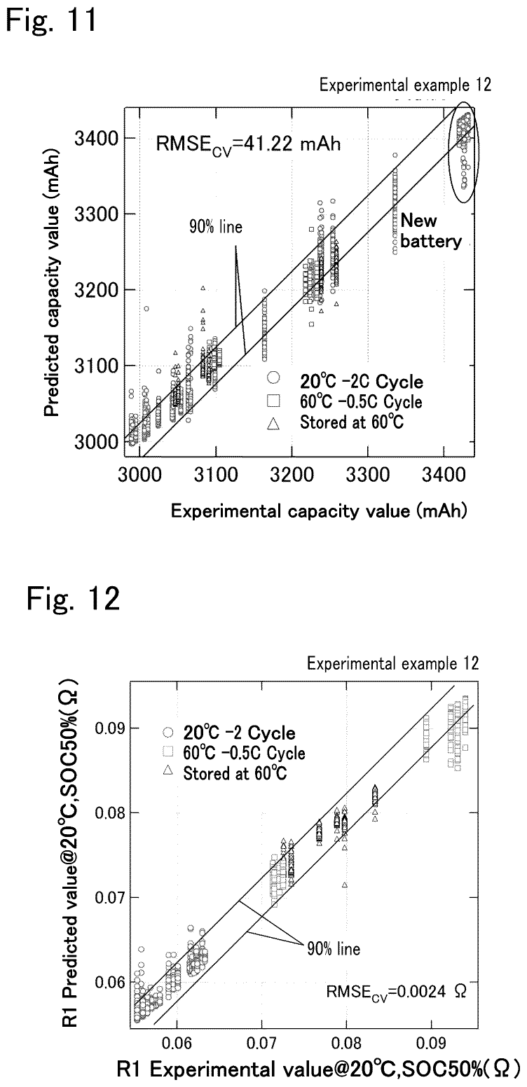

FIG. 11 is a relationship graph between the experimental capacity value and the predicted capacity value of each battery deteriorated in a plurality of deterioration modes with the real part Z′, the imaginary part Z″ of the impedance, the open voltage V, the measurement temperature T used as the explanatory variables (Experimental Example 12). FIG. 12 is a relationship graph between the experimental capacity value and the predicted resistance value of each battery deteriorated in a plurality of deterioration modes with the real part Z′, the imaginary part Z″ of the impedance, the open voltage V, the measurement temperature T used as the explanatory variables (Experimental Example 12). In FIG. 12, error lines are shown, between which 90% of the entire data is included. As shown in FIG. 11, it has been found that for batteries in any deterioration mode, the capacity is predictable with high accuracy. In particular, it has been found that for a battery capacity of approximately 3000 mAh, 90% or more of the data is predictable with an error of ±25 mAh. In addition, as shown in FIG. 12, it has been found that for batteries in any deterioration mode, the resistance is predictable with high accuracy.

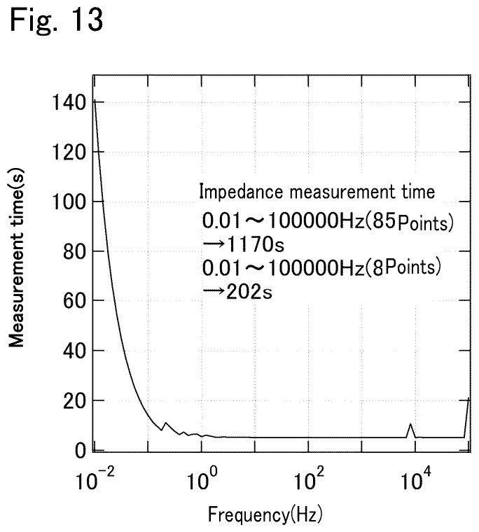

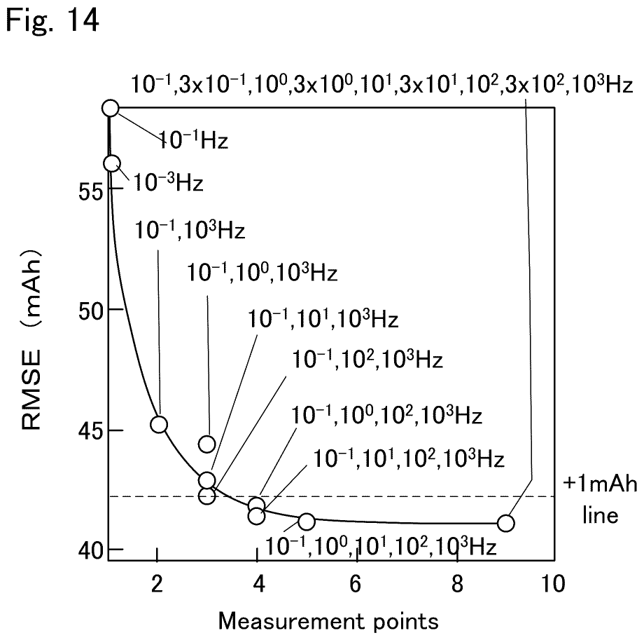

FIG. 13 is a relationship graph between frequency (Hz) and measurement time (s). It is desirable that battery diagnosis be performed in a short time. In this respect, since the impedance values of close frequencies are strongly correlated, even if data points to be measured are thinned to some extent, it is expected that deterioration diagnosis is not affected. Thus, the number of data points to be measured may be reduced. For example, when impedance of 0.01 to 100000 Hz is plotted at 85 points evenly on a log scale of frequency, the measurement time was 1170 s, whereas when 8 points (0.01, 0.1, 1, 10, 100, 1000, 10000, 100000 Hz) are plotted, it has been found that the measurement time was 202 s which is approximately ⅕ the former measurement time. When the battery capacity is directly measured with 0.1 C, it takes at least 10 hours for measurement, thus the measurement time for impedance is extremely shorter than the battery capacity measurement time, which is suited for deterioration diagnosis.

Next, Table 4 shows the used frequency band dependence of the result of prediction of battery capacity by RF with the imaginary part Z″ of the impedance added. FIG. 14 is a relationship graph between number of measurement points and RMSE (mAh). As shown in Table 4, FIG. 14, regarding the number of measurement points of data, it has been found that the number of measurement points corresponding to the used frequency is preferably, 3 points or greater, and high prediction accuracy is achieved with 4 points or greater. The prediction accuracy is substantially the same between the case of 6 measurement points and the case of 3 measurement points, thus it is inferred that even if the number of measurement points is further increased, the prediction accuracy is unlikely to be improved. When the number of measurement points of data is increased, it takes time for diagnosis, thus it is inferred that desirably, the number of measurement points is 8 points or less, more desirably, 6 points or less.

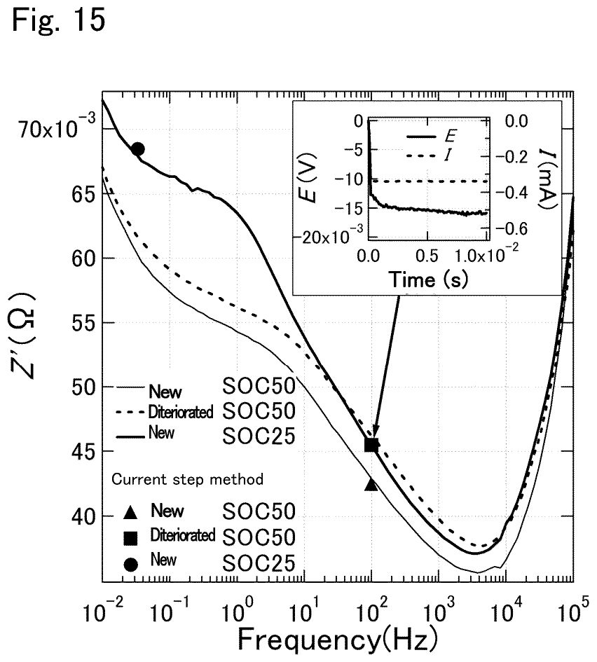

The measurement at the time of deterioration diagnosis may be direct measurement of impedance; however, the case of indirect measurement was also studied. As an example, a current step method was studied. FIG. 15 is an explanatory graph showing a correspondence relationship between the frequency dependence of Z′ at the measurement temperature 20° C., and Z′ in each frequency determined by the current step method. In FIG. 15, the behavior of voltage when a current of 0.1 C is applied for 0.01 s by the current step method is supplemented. Using the current and voltage, Z′ of the deteriorated battery (the remaining capacity SOC at 50% at the measurement temperature 20° C.) at 100 Hz in FIG. 15 was determined by the Laplace transform. As shown in FIG. 15, it has been found that the impedance Z′ determined by the current step method corresponds to the measurement result of directly determined impedance with significantly high accuracy. From this result, it is inferred that a favorable result is obtained by using, as the technique for deterioration diagnosis, the voltage step method or the current pulse method other than the current step method.

TABLE 1

| Experimental | Machine | Explanatory | RMSE |
|---|---|---|---|
| Examples | learning method | variable | (mAh) |
| 1 | nnet | Z’ | 71.52 |
| 2 | nnet | Z’, V | 68.83 |
| 3 | nnet | Z’, V, T | 65.48 |
| 4 | RF | Z’ | 74.43 |
| 5 | RF | Z’, V | 57.88 |
| 6 | RF | Z’, V, T | 54.76 |
| 7 | RF | V, T | 109.5 |

Z’ Real part Z
nnet Neural network
V Open voltage (V)
RF Random Forest
T Measurement temperature (° C.)
Used frequency at Z’ is 10⁻², 10⁻¹, 10⁰, 10¹, 10², 10³, 10⁴, 10⁵ Hz.

TABLE 2

| Experimental | Explanatory | Used frequency at | RMSE | Measurement |
|---|---|---|---|---|
| Examples | variable | Z’ (Hz) | (mAh) | time (sec) |
| 6 | Z’, V, T | 10⁻², 10⁻¹, 10⁰, 10¹, 10², | 54.76 | 202 |
| | | 10³, 10⁴, 10⁵ | | |
| 8 | Z’, V, T | 10⁻², 10⁻¹, 10⁰, 10¹, 10², | 50.52 | 194 |
| | | 10³, 10⁴ | | |
| 9 | Z’, V, T | 10⁻², 10⁻¹, 10⁰, 10¹, 10², | 44.67 | 189 |
| | | 10³ | | |
| 10 | Z’, V, T | 10⁻², 10⁻¹, 10⁰, 10¹, 10² | 48.35 | 184 |
| 11 | Z’, V, T | 10⁻¹, 10⁰, 10¹, 10², 10³ | 45.62 | 49 |

Machine learning method is RF.

TABLE 3

| Experimental | Explanatory | RMSE |
|---|---|---|
| Examples | variable | (mAh) |
| 11 | Z’, V, T | 45.62 |
| 12 | Z’, Z”, V, T | 41.22 |
| 13 | Z’, Z”, V | 41.80 |
| 14 | Z”, V, T | 46.61 |

1) Used frequency at Z’ , Z” is 10⁻¹, 10⁰, 10¹, 10², 10³ Hz.
2) Machine learning method is RF.

TABLE 4

| Experimental | Explanatory | Used frequency at Z’ , | RMSE | Measurement |
|---|---|---|---|---|
| Examples | variable | Z” (Hz) | (mAh) | time (sec) |
| 12 | Z’, Z”, V, T | 10⁻¹, 10⁰, 10¹, 10², 10³ | 41.22 | 49 |
| 15 | Z’, Z”, V, T | 10⁻², 10⁻¹, 10⁰, 10¹, | 41.73 | 189 |
| | | 10², 10³ | | |
| 16 | Z’, Z”, V, T | 10⁰, 10¹, 10², 10³ | 41.72 | 35 |
| 17 | Z’, Z”, V, T | 10⁻², 10⁻¹, 10⁰, 10¹, 10², | 51.52 | 202 |
| | | 10³, 10⁴, 10⁵ | | |
| 18 | Z’, Z”, V, T | 10⁻², 10⁻¹, 10⁰, 10¹, | 44.87 | 194 |
| | | 10², 10³, 10⁴ | | |
| 19 | Z’, Z”, V, T | 10⁻², 10⁻¹, 10⁰, 10¹, 10² | 44.44 | 184 |

1) Machine learning method is RF.

Next, the effect of the type of lithium-ion secondary battery was studied. In order to identify the types of batteries, Random Forest (RF) was used in the statistical analysis software R to classify the batteries. Hyper parameters ntree, mtry were calculated with ntree=10000, mtry=5, respectively. 10-fold cross validation was adopted to construct 10-time estimation model 10, and evaluation was made with the average Accuracy (correct answer rate) for 10 times. The real part Z′ and the imaginary part Z″ of the AC impedance (0.1, 1, 10, 100, 1000 Hz), the open voltage V, the measurement temperature T were used as the explanatory variables, and evaluation was made with 3696 points for LIB manufactured by Panasonic, 792 points for LIB manufactured by LG, 528 points for LIB sold by PLATA as the number of data points. As a result, it could be identified that the batteries are classified into three types with Accuracy of 0.998, that is substantially 100% of probability. It is inferred that the technique of measurement factor and type identification preferably has the above-described contents as shown in Tables 1 to 4. The advantages of being able to identify the type of a battery in advance like this will be described in the following.

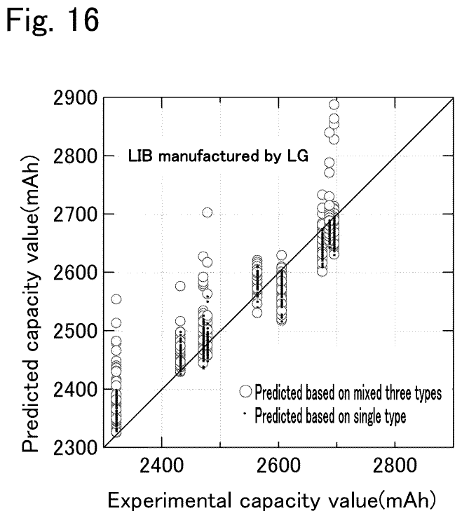

In order to estimate the capacity and the resistance of each battery, Random Forest was used in the statistical analysis software R to construct a type estimation model. Hyper parameters ntree, mtry were set with ntree=10000, mtry=5, respectively, and the capacity and the resistance of each battery was predicted by the measurement results of the AC impedance (0.1, 1, 10, 100, 1000 Hz), the open voltage V, and the measurement temperature T. The results of a single type (LIB manufactured by Panasonic) are illustrated in FIGS. 11, 12 mentioned above. Next, the case where an estimation model is constructed using all the measurement results for the three types of battery was compared with the case where an estimation model is constructed by classifying the measurement results into the types. FIG. 16 is a relationship graph between experimental capacity value and predicted capacity value which are predicted based on single type or mixed three types. FIG. 16 is a result of comparison between the experimental capacity value and the predicted capacity value of each LIB manufactured by LG. In the case where an estimation model is constructed using all the measurement results for the three types of battery, part of the predicted values resulted in being away from the experimental values significantly, as compared to the case of a database of a single type battery. This result occurs in the same manner as in LIB manufactured by Panasonic and LIB sold by PLATA. In other words, it has been found that to increase the prediction accuracy, a favorable result is obtained by rather constructing an estimation model only with the measurement results of a single type battery. When the type of a battery is not identifiable, there is no other choice but to mix the databases of a plurality of types of battery to construct an estimation model, thus it has been clarified that identifying the type of battery in advance leads to the improvement of the prediction accuracy.

### Study about Diversion of Data Set of Different Product Types

For study of deterioration diagnosis for used batteries, lithium-ion battery (LIB) NCR18650 manufactured by Panasonic was used as a first battery, and 18650-M26 manufactured by LG was used as a second battery, and the measurement results of the AC impedance Z, the open voltage V, and the measurement temperature T were used for diagnosis. For measurement of impedance, open voltage, and measurement temperature, CELLTEST-8T (7ch: 1A specifications, 1ch: 25A specifications) manufactured by Solar Tron Company was used, and the AC voltage amplitude at the time of measurement was set to 5 mA. As the deteriorated batteries of LIB manufactured by Panasonic, the ones (also referred to as high-rate batteries) which had been charged with 2 C (C rate) at 20° C., and discharged with 0.1 C repeatedly, and the ones (also referred to as high-temperature stored batteries) in which batteries with a remaining capacity SOC adjusted to 100% (4.2V) had been stored for a long time were prepared. The impedance and the open voltage vary with the SOC of each battery and the measurement temperature, so measurement was made with SOC in the range of 0 to 100% with increments of 10%, and a measurement temperature in the range of −20 to 50° C. with increments of 10° C. As the index of the degree of deterioration, the battery capacity was considered this time. This time, 5V/10A-80CH manufactured by Asuka Electronics Co., Ltd was used for each battery to measure the discharged capacity of CCCV discharge with 0.1 C at 20° C., and the battery capacity was determined to be the discharged capacity. Based on the obtained database, the capacity was designed to be predictable from the measurement results of the AC impedance Z (0.1, 1, 10, 100, 1000 Hz), the open voltage V (V), the measurement temperature T (° C.) by machine learning at a temperature of −20 to 50° C., with SOC in the range of 0 to 100%.

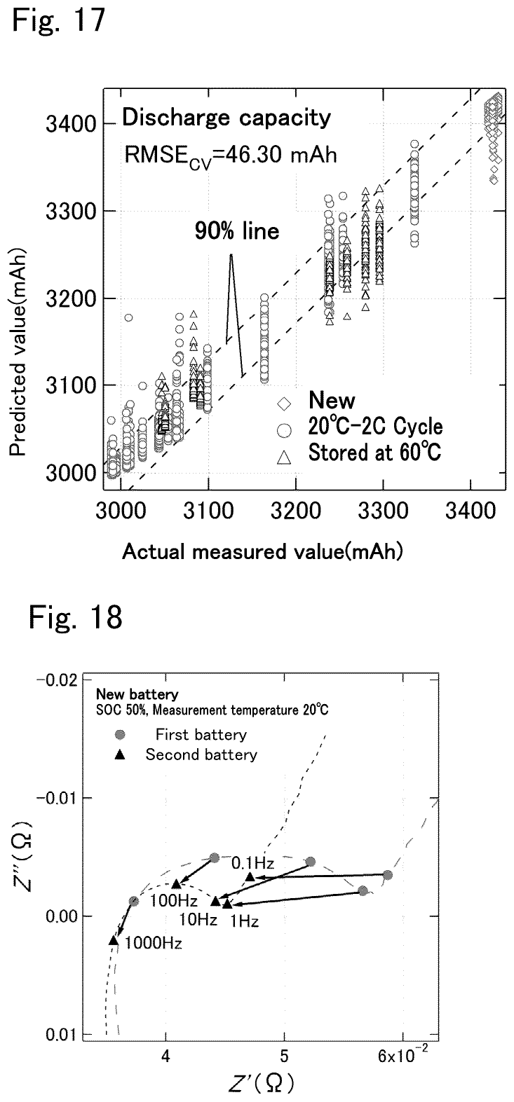

In order to estimate the capacity of a battery, Random Forest (RF) was used in the statistical analysis software R to construct a prediction model. Hyper parameters ntree, mtry were set with ntree=10000, mtry=8, respectively, and the capacity of LIB manufactured by Panasonic was predicted by the measurement results of the AC impedance (0.1, 1, 10, 100, 1000 Hz), the open voltage, and the measurement temperature. Actual measured data in 88 conditions (8 temperature conditions×11 SOC conditions) was obtained using 7 new batteries, 21 high-rate batteries, and 8 high-temperature stored batteries, and a prediction model was constructed from the database including 3164 data points excluding abnormal values in the actual measured data. FIG. 17 is a relationship graph between predicted value using the prediction model and actual measured value. In FIG. 17, boundary lines are shown, between which 90% of the measurement results is included. In this study, 10-fold cross validation is performed, thus 10-time estimation model 10 is constructed from training data, and the average RMSE of test data for 10 times, that is, RMSE_{CV} is also shown in FIG. 17. RMSE_{CV} of the prediction model studied here was 46.30 mAh. As shown in FIG. 17, the prediction value (capacity) predicted using the database of the first battery has a favorable correspondence relationship with the actual measured value, and it has been verified that the prediction model can make prediction for a value close to the actual measured value.

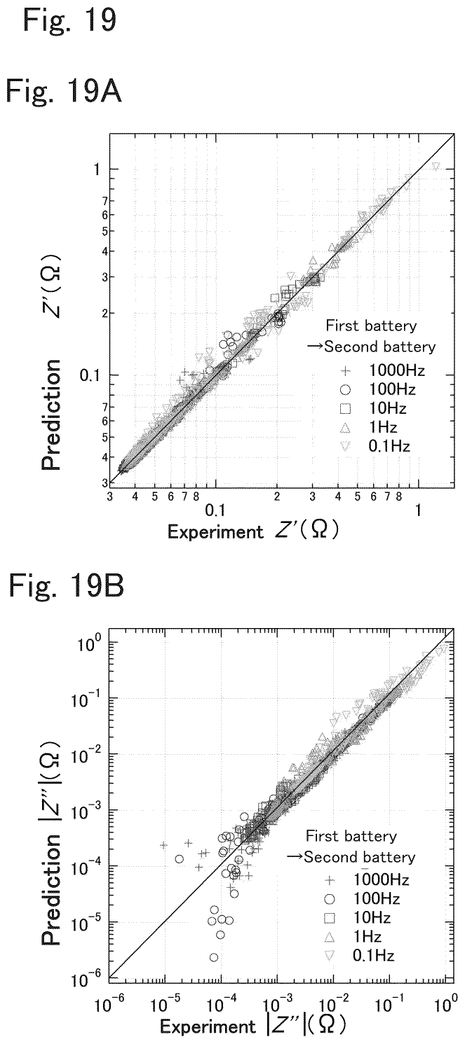

Next, a conversion model of converting the impedance of LIB manufactured by Panasonic as the first battery into the impedance of LIB manufactured by LG as the second battery was constructed by machine learning, and diversion of the database used for construction of the prediction model was studied. One new battery, one high-rate battery, and one high-temperature stored battery each as the second battery are associated with those as the first battery one-to-one. FIG. 18 is an example of impedance (the real part Z′, the imaginary part Z″) of a new battery with SOC of 50% at temperature 20° C. As shown in FIG. 18, it was predicted that the measurement results of the first battery can be converted to the measurement results of the second battery. Next, Random Forest was used in the statistical analysis software R for the data in 88 conditions, and hyper parameters were set with ntree=10000, mtry=5, then an impedance conversion model was constructed. Z′ (f) and Z″ (f) at the frequency f (f=0.1, 1, 10, 100, 1000 Hz) of the second battery are used as the objective variables, and Z′ (f) and Z″ (f) at the frequency f of the first battery, the temperature T, and the open voltage V are used as the explanatory variables. FIG. 19 is a relationship graph between predicted value of impedance predicted using the conversion model and experimental value, FIG. 19A shows the real part Z′, and FIG. 19B shows the imaginary part Z″. Here, predicted results at 264 data points (3 batteries×88 conditions) by the conversion model are shown. Here, 3164 data points of the first battery were converted to the impedance of the second battery using the constructed conversion model. In other words, a post-conversion database with 3164 data points greater in number than the database of the second battery was obtained by the second database including 264 data points of the second battery, and the conversion model. As shown in FIG. 19, it has been found that when the post-conversion database with data points increased in number using the conversion model is used, actual measured values and predicted values are favorably associated with each other. Note that FIG. 19B is shown on log scale, and a correspondence relationship in a region of 3×10⁻⁴ or less seems unfavorable, but this is a region of approximately value 0, and in particular, the correspondence relationship is determined to have no problem.

### Study of Abnormal Value Determination

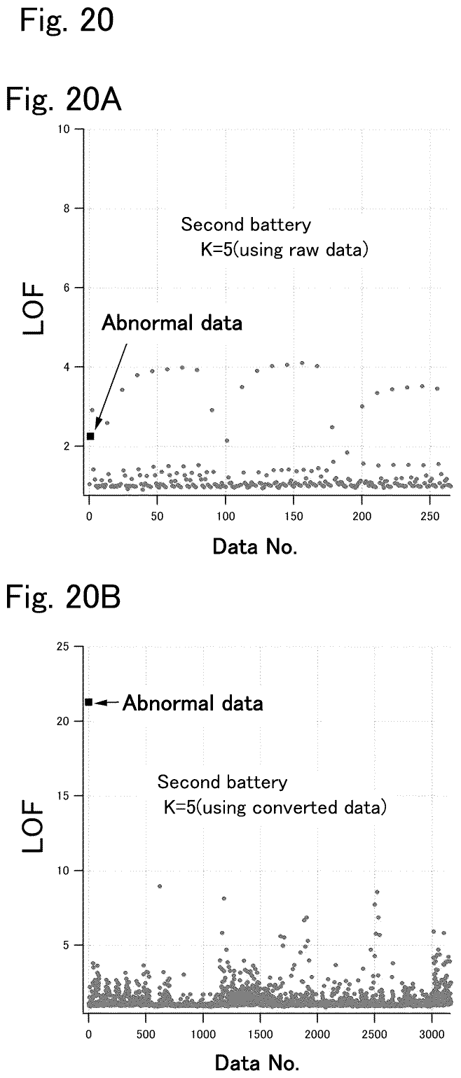

Next, the case where a post-conversion database expanded by the constructed conversion model is used for abnormal value determination was studied. Abnormal data was added to 264 data points of the second battery, and abnormal data was added to 3164 data points obtained by the conversion model, then abnormal value detection was attempted. The abnormal data has a value such that only the impedance of data of a new second battery with SOC of 50% at 20° C. is intentionally reduced by two orders of magnitude. For machine learning to perform abnormal value detection, the statistical analysis software R was used, and Local Outlier Factor (LOF) was used as the technique. FIG. 20 is a relationship graph between data No. and LOF of the second battery with abnormal data added, FIG. 20A shows a detection result using a database of only actual measured values of the second battery, and FIG. 20B shows a detection result using a post-conversion database with data points expanded by a conversion model. Here, the real part Z′ and the imaginary part Z″ of the AC impedance (0.1, 1, 10, 100, 1000 Hz), the open voltage V, and the measurement temperature T were used as the parameters to calculate LOF, thus evaluation was made in a 12-dimensional space. A high score of LOF indicates a low data density around the data with respect to space, which can be regarded as an abnormal value. In FIG. 20, hyper parameter k is calculated with k=5, and the horizontal axis is the management number of battery data. As shown in FIG. 20A, at 264 data points which are raw data of the second battery, the LOF of abnormal data indicates approximately two, which is nearly equal to the LOF of other normal data, and abnormal data could not be found. In contrast, when a post-conversion database is used, which refers to 3164 data points obtained by an impedance conversion model, the LOF of abnormal data indicates 20 or greater, thus it has been found that poor measurement and abnormal measurement results can be extracted using a predetermined threshold (for example, the score of LOF is greater than or equal to 10, or greater than or equal to 15). As shown in FIG. 20A, when a referred database is not enriched, abnormal value detection is difficult, and the referred database can be enriched using the present technique. The present technique in this case is to construct a conversion model by associating the impedance of a specific battery type with the impedance of another battery type one-to-one. For machine learning, the statistical analysis software R was used, and it is inferred that a similar result is obtained even in an environment such as python, matlab, excel. As the technique to construct a conversion model, Random Forest (RF) was used, and it is inferred that a similar result is obtained by linear regression, neural network, support vector machine, boosting.

### Study of Battery Type Determination

Next, the battery type is attempted to be identified using a post-conversion database including 264 data points of the second battery, and additional 3164 data points of the first battery obtained by the conversion model. Random Forest was used in the statistical analysis software R, and the real part Z′ and the imaginary part Z″ of the AC impedance (0.1, 1, 10, 100, 1000 Hz), the open voltage V, and the measurement temperature T were used as the explanatory variables, then batteries were classified with hyper parameters ntree=10000, mtry=5. 10-fold cross validation was adopted, and evaluation was made with the average correct answer rate for 10 times. When only 264 data points of raw data were used, the correct answer rate was 0.994; however, when 3164 data points obtained by the conversion model were used, the correct answer rate was 0.999, thus the correct answer rate has significantly improved. Like this, when the database used for prediction is not enriched, the correct answer rate for identification of battery type is low; however, a referred database can be enriched using the present technique, and it has been found that the correct answer rate can be improved.

### Study of Capacity Determination

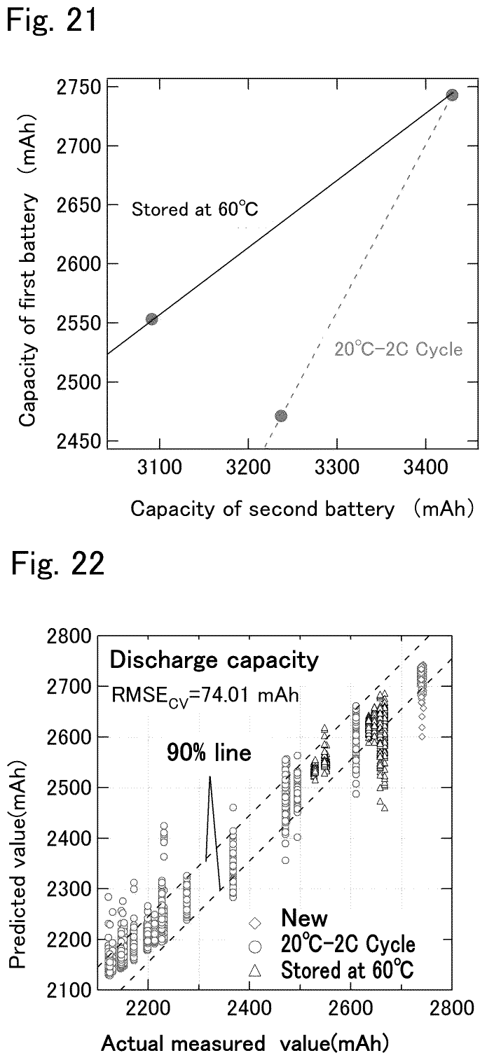

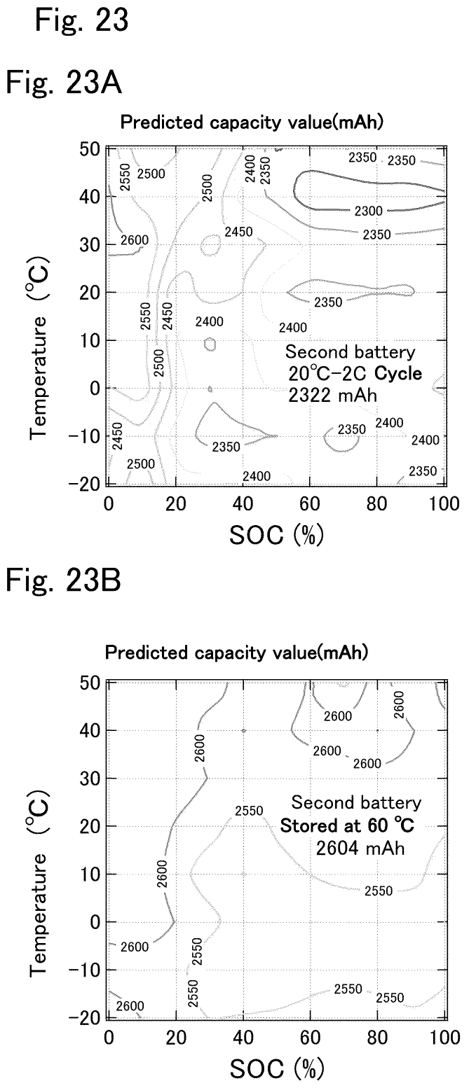

As described above, it has been found that with the post-conversion database of the second battery with data points expanded by converting, using the conversion model, the database of the first battery greater in number of data points than the database of the second battery, more accurate abnormal value determination and battery type determination are possible. Next, the case where a capacity prediction model is constructed using the post-conversion database was studied. FIG. 21 is a relationship graph between the capacities of three second batteries and the capacities of corresponding first batteries. The capacity of each first battery was converted to the capacity of a second battery using the linear interpolation of FIG. 20. Let y be the capacity of the second battery, and x be the capacity of the first battery, then in the case of high-rate battery, y=1.41x−2091, and in the case of high-temperature stored battery, y=0.56x+821. In the statistical analysis software R, with Random Forest (RF), the real part Z′ and the imaginary part Z″ of the AC impedance (0.1, 1, 10, 100, 1000 Hz), the open voltage V, and the measurement temperature T were used as the explanatory variables, and a capacity prediction model was constructed using the post-conversion database with hyper parameters ntree=10000, mtry=8. FIG. 22 is a relationship graph between actual measured values and predicted capacity values obtained by a prediction model constructed using the post-conversion database. The capacities of a high-rate battery (2322 mAh), a high-temperature stored battery (2604 mAh) prepared for evaluation were predicted using the prediction model. FIG. 23 is a resultant graph of the capacity of a deteriorated battery predicted with a prediction model constructed using the post-conversion database. FIG. 23A shows a prediction result for a high-rate battery, and FIG. 23B shows a prediction result for a high-temperature stored battery. It has been found that with a prediction model using the conversion database, as shown in FIG. 22, prediction can be made with an error of approximately RMSE_{CV}=74.01 mAh. Table 5 collectively shows average errors in 88 conditions (8 temperature conditions×11 SOC conditions) for capacity prediction for high-rate battery (2322 mAh), high-temperature stored battery (2604 mAh) based on a prediction model using the conversion database, and a prediction model constructed only from 264 data points (raw data) of the second battery. It has been found that with a prediction model using the post-conversion database, a low RMSE_{CV} is achieved, and the prediction accuracy can be improved by expanding the database through diversion of the data of the first battery. As shown in FIG. 23, a distribution of prediction accuracy, such as a region where a prediction result is excellent, and a region where a prediction result is good can be obtained. Regarding the diversion of database by conversion thereof, the AC impedance Z′, Z″, the open voltage V, the measurement temperature T are used in this embodiment; however, it is inferred that the present technique is effective for deterioration estimation using a DC current, a voltage response, a magnetic field, a strain gauge and the like.

TABLE 5

| | | Average errors (Difference | |
|---|---|---|---|
| | | from actual measured value) | |
| | Actual | Using post- | Using actual |
| | measured | conversion | measured |
| | value | database | database |
| 20° C.-2C cycle | 2322 mAh | 100.97 mAh | 181.65 mAh |
| batteries | | | |
| 60° C. stored | 2604 mAh | 40.14 mAh | 62.29 mAh |
| batteries | | | |

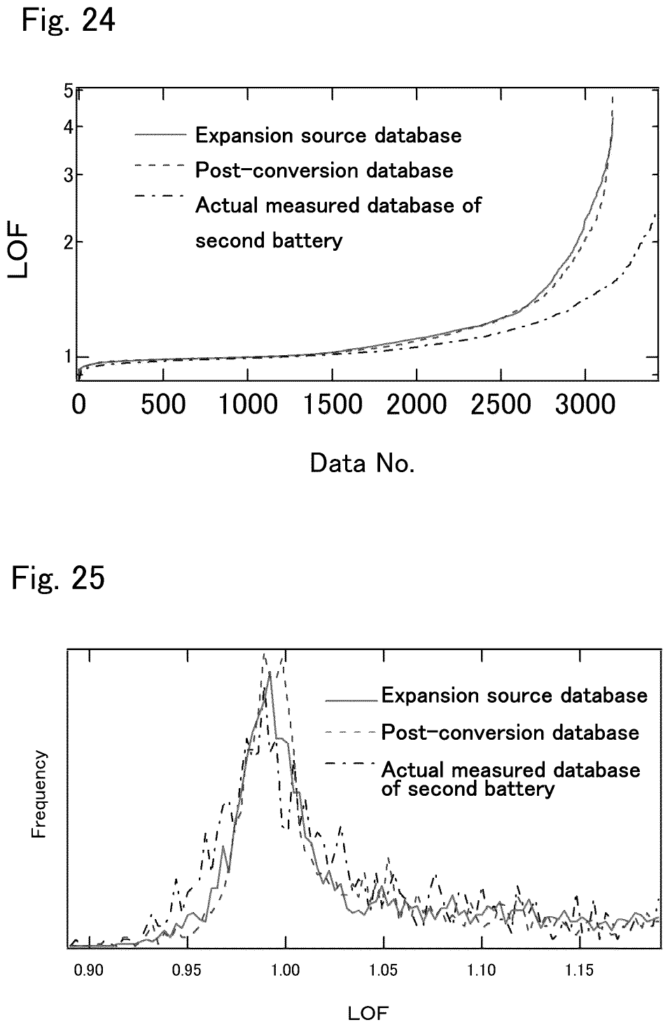

Next, a technique to quantitatively evaluate whether the database in use is a post-conversion database was studied. The degrees of dispersion of data with respect to space of the post-conversion database and the expansion source database (database of the first battery) are close to each other. However, as in Table 6, the degrees of dispersion of data with respect to space in the expansion source database and the post-conversion database are difficult to be clearly distinguished from each other at a glance. Table 6 shows part of the database consisting of 3164 data points of the LIB manufactured by Panasonic as the expansion source first battery, and part of a post-conversion database consisting of 3164 data points, the post-conversion database being diverted to the LIB manufactured by LG as the second battery. First, the LOF of each piece of data in the database was calculated with hyper parameter k=15. The real part Z′ and the imaginary part Z″ of the AC impedance (0.1, 1, 10, 100, 1000 Hz), the open voltage V, and the measurement temperature T were used as the parameters to calculate LOF, thus evaluation was made in a 12-dimensional space. A high score of LOF indicates a low data density around the data with respect to space. FIG. 24 is a resultant graph obtained through sorting in ascending order of LOF. The horizontal axis indicates the management number of battery data. It has been found that the expansion source database and the post-conversion database have a similar tendency. FIG. 24 also shows a result of actual measured database consisting of only raw data of the second battery. The actual measured database of the second battery in this case refers to 3417 points produced in the following manner: measurement in 88 conditions (8 temperature conditions×11 SOC conditions) is performed on 2 new batteries, 20° C. to 2C cycle 7 batteries, 4 stored batteries at 60° C. to create a database, and 1139 data points excluding abnormal values in the database are duplicated three times to produce 3417 points. Next, the histogram of calculated LOF in each of the databases was calculated. A histogram was generated using 101 points with a start point of LOF at 0.89 and increments of 0.003. FIG. 25 is a relationship graph between LOF and frequency. In the actual measured database of the second battery, it was observed that LOF has the strongest peak around 0.98, whereas precision of frequency around 0.95 is low. How the post-conversion database and the actual measured database of the second battery are similar to the expansion source database was evaluated using 101 points of the histogram in terms of correlation coefficient, and the histogram (the degree of dispersion of data) was quantitatively evaluated. The result is shown in Table 7. A correlation coefficient closer to 1 indicates that the databases are similar, and it has been found that the post-conversion database is clearly more similar to the expansion source database than to the actual measured database. Although the results of the expansion source database and the post-conversion database are shown, the degrees of dispersion of the post-conversion databases are naturally closer to each other, thus it is readily understood that the correlation coefficient is high. Based upon the foregoing, implementation of the present invention can be found, for example, when the databases of battery A and battery B in the apparatus are compared, and the correlation coefficient is 0.95 or higher, the databases are determined to be the post-conversion databases. Even if the apparatuses are different, when the correlation coefficient between respective databases of battery A of apparatus A, and battery B of apparatus B is 0.95 or higher, it can be determined that the databases are post-conversion databases. In other words, it can be determined that the present invention has been implemented.

TABLE 6

| Open voltage | Temperature | Real part Z′ of impedance | | | | | | Imaginary part Z″ | |
|---|---|---|---|---|---|---|---|---|---|
| (V) | (° C.) | 10³ Hz | 10² Hz | 10¹ Hz | 10⁰ Hz | 10⁻¹ Hz | . . . | 10³ Hz | . . . |

Database of source of conversion

| | | | | | | | | | |
|---|---|---|---|---|---|---|---|---|---|
| 2.8879 | −10 | 0.0754 | 0.103 | 0.141 | 0.224 | 0.391 | . . . | −0.0150 | . . . |
| 3.3682 | −10 | 0.0689 | 0.0933 | 0.127 | 0.189 | 0.303 | . . . | −0.0133 | . . . |
| 4.1792 | −10 | 0.0598 | 0.0915 | 0.131 | 0.184 | 0.273 | . . . | −0.0157 | . . . |
| 3.494 | −10 | 0.0630 | 0.0847 | 0.115 | 0.172 | 0.316 | . . . | −0.0116 | . . . |
| 3.5674 | −10 | 0.0604 | 0.0812 | 0.111 | 0.168 | 0.317 | . . . | −0.0109 | . . . |
| . | . | . | . | . | . | . | . | . | . |
| . | . | . | . | . | . | . | . | . | . |
| . | . | . | . | . | . | . | . | . | . |

Post-conversion database

| | | | | | | | | | |
|---|---|---|---|---|---|---|---|---|---|
| 2.8879 | −10 | 0.0616 | 0.0827 | 0.112 | 0.177 | 0.314 | . . . | −0.00651 | . . . |
| 3.3682 | −10 | 0.0556 | 0.0715 | 0.112 | 0.152 | 0.328 | . . . | −0.00612 | . . . |
| 4.1792 | −10 | 0.0484 | 0.0666 | 0.105 | 0.130 | 0.221 | . . . | −0.00492 | . . . |
| 3.494 | −10 | 0.0556 | 0.0701 | 0.0926 | 0.150 | 0.276 | . . . | −0.00597 | . . . |
| 3.5674 | −10 | 0.0488 | 0.0693 | 0.0912 | 0.150 | 0.218 | . . . | −0.00515 | . . . |
| . | . | . | . | . | . | . | . | . | . |
| . | . | . | . | . | . | . | . | . | . |
| . | . | . | . | . | . | . | . | . | . |

TABLE 7

| | Data | Correlation |
|---|---|---|
| | points | coefficient |
| Post-conversion | 3164 | 0.96 |
| database | | |
| Actual measured | 264 | 0.89 |
| database | | |

Note that the evaluation device, the evaluation system, the evaluation method and its program disclosed in the present description are not limited to the above-described examples, and it is needless to say that an embodiment may be implemented in various manners as long as the embodiment belongs to the technical scope of the present disclosure.

The present application claims priority from Japanese Patent Application No. 2021-117063, filed on Jul. 15, 2021, the entire contents of which are incorporated herein by reference.

### Industrial Applicability

The evaluation device, the evaluation system, the evaluation method and its program disclosed in the present description are applicable to the technical field of evaluation of characteristics of power storage devices.

### REFERENCE SIGNS LIST

10 EVALUATION SYSTEM, 12 NETWORK, 13 POWER STORAGE DEVICE, 14 PROCESS TARGET, 15 MEASUREMENT DEVICE, 16 CONSTANT TEMPERATURE BATH, 17 AC IMPEDANCE ANALYZER, 18 INPUT DEVICE, 19 DISPLAY DEVICE, 20 EVALUATION DEVICE, 21 CONTROLLER, 22 STORAGE, 23 FIRST DATABASE, 24 IMPEDANCE, 25 OPEN VOLTAGE, 26 MEASUREMENT TEMPERATURE, 27 DEGREE OF DETERIORATION, 28 SECOND DATABASE, 30 MACHINE LEARNING PROGRAM, 31 TOLERANCE LEVEL, 32 CONVERSION MODEL, 33 TYPE ESTIMATION MODEL, 34 CHARACTERISTICS ESTIMATION MODEL, 35 OUTLIER DETECTION PROGRAM, 36 TYPE ESTIMATION PROGRAM, 37 DETERIORATION DETERMINATION PROGRAM, 40 DISPLAY SCREEN

1. An evaluation device that evaluates a power storage device including a plurality of types, the evaluation device comprising a controller including a first database that contains as data a measurement factor of a first type power storage device; a second database that contains as data a measurement factor of a second type power storage device different from the first type power storage device; and a conversion model that converts data by machine learning using the measurement factors of the power storage devices, the controller being configured to convert the data in the first database to the data in the second database using the conversion model, obtain a post-conversion database with data points greater in number than data points of the second database, and perform evaluation related to the second type power storage device using the post-conversion database.

2. The evaluation device according to claim 1,
wherein the controller constructs the conversion model by associating the measurement factor of the first type with the measurement factor of the second type one-to-one by machine learning.

3. The evaluation device according to claim 1,
wherein the controller obtains the post-conversion database using the first database having data points greater in number than data points of the second database.

4. The evaluation device according to claim 1,
wherein the controller constructs a characteristics estimation model for estimating characteristics including a capacity and/or a resistance of the second type power storage device by machine learning using the measurement factors included in the post-conversion database.

5. The evaluation device according to claim 4,
wherein the controller obtains a measurement result of a measurement factor of a power storage device as a process target, and uses the obtained measurement factor as an explanatory variable to estimate characteristics of the power storage device as the process target from the characteristics estimation model.

6. The evaluation device according to claim 5,
wherein the controller determines a degree of deterioration of the power storage device as the process target based on the estimated characteristics.

7. The evaluation device according to claim 1,
wherein the controller constructs a type estimation model for estimating a type of the second type power storage device by machine learning using the measurement factors included in the post-conversion database.

8. The evaluation device according to claim 7,
wherein the controller obtains a measurement result of a measurement factor of the second type power storage device as a process target, and uses the obtained measurement factor as an explanatory variable to estimate a type of the power storage device as the process target from the type estimation model.

9. The evaluation device according to claim 1,
wherein the controller uses the measurement factors included in the post-conversion database to derive an evaluation value by a predetermined outlier detection technique, related to the second type power storage device, and constructs a tolerance level of outlier for the second type power storage device based on the evaluation value.

10. The evaluation device according to claim 9,
wherein the controller obtains a measurement result of a measurement factor of the power storage device as a process target, uses a measurement factor as an explanatory variable, the measurement factor excluding a measurement result for which the evaluation value obtained by the outlier detection technique using the obtained measurement factor is out of the tolerance level, and performs evaluation related to the power storage device as the process target.

11. The evaluation device according to claim 9,
wherein the controller uses LOF (Local Outlier Factor) as the outlier detection technique.

12. The evaluation device according to claim 1,
wherein the controller uses Random Forest as a technique for the machine learning.

13. The evaluation device according to claim 1,
wherein the measurement factors include at least a real part and/or an imaginary part of an impedance of the power storage device, an open voltage of the power storage device, and measurement temperatures of the impedance and the open voltage.

14. The evaluation device according to claim 1,
wherein the measurement factors include an impedance in a range of 10⁻² Hz or higher and lower than 10⁴ Hz.

15. An evaluation system that evaluates a power storage device, the evaluation system comprising:
a measurement device that obtains a measurement result of a measurement factor of the power storage device; and
the evaluation device according to claim 1,
wherein the controller obtains the measurement result of the power storage device from the measurement device.

16. An evaluation method for performing evaluation of a power storage device including a plurality of types, wherein a first database that contains as data a measurement factor of a first type power storage device; a second database that contains as data a measurement factor of a second type power storage device different from the first type power storage device; and a conversion model that converts data by machine learning using the measurement factors of the power storage devices are provided, the evaluation method comprising: a conversion step for converting the data in the first database to the data in the second database using the conversion model, and obtaining a post-conversion database with data points greater in number than data points of the second database; and
an evaluation step for performing evaluation related to the second type power storage device using the post-conversion database.

17. A storage medium storing program causing one or a plurality of computers to execute the steps in the evaluation method according to claim 16.
